(19) United States
(12) Patent Application Publication
(10) Pub. No.: US 2015/0287766 A1
(43) Pub. Date: Oct. 8, 2015

(54) UNIT PIXEL OF AN IMAGE SENSOR AND IMAGE SENSOR INCLUDING THE SAME

(71) Applicants: Tae-Chan Kim, Yongin-si (KR); June-Taeg Lee, Suwon-si (KR); Dong-Ki Min, Seoul (KR); Sang-Chul Sul, Suwon-si (KR); Myung-Won Lee, Hwaseong-si (KR); Tae-Yon Lee, Seoul (KR); Jung-Kyu Jung, Seoul (KR)

(72) Inventors: Tae-Chan Kim, Yongin-si (KR); June-Taeg Lee, Suwon-si (KR); Dong-Ki Min, Seoul (KR); Sang-Chul Sul, Suwon-si (KR); Myung-Won Lee, Hwaseong-si (KR); Tae-Yon Lee, Seoul (KR); Jung-Kyu Jung, Seoul (KR)

(21) Appl. No.: 14/676,399

(22) Filed: Apr. 1, 2015

Related U.S. Application Data
(60) Provisional application No. 61/974,116, filed on Apr. 2, 2014.
(60) Provisional application No. 61/979,921, filed on Apr. 15, 2014.

(30) Foreign Application Priority Data
Sep. 30, 2014 (KR) 10-2014-0130817

(51) Int. Cl. H01L 27/30; H01L 27/146

(52) U.S. Cl. CPC H01L 27/307; H01L 27/14621

(57) ABSTRACT

A unit pixel of an image sensor is provided. The unit pixel includes a visible light detection layer and an infrared light detection layer disposed on the visible light detection layer. The visible light detection layer includes visible light pixels and color filters configured to detect visible light to output first charges. The infrared light detection layer includes at least one infrared light pixel configured to detect infrared light to output second charges.

### CROSS-REFERENCE TO RELATED APPLICATIONS

This application claims priority under 35 U.S.C. §119 to U.S. Provisional Application No. 61/974,116, filed on Apr. 2, 2014, in the USPTO, U.S. Provisional Application No. 61/979,921, filed on Apr. 15, 2014, in the USPTO, and Korean Patent Application No. 10-2014-0130817, filed on Sep. 30, 2014, in the Korean Intellectual Property Office (KIPO), the disclosures of which are incorporated by reference herein in their entireties.

### TECHNICAL FIELD

The present inventive concept relates to an image sensor, and more particularly, to a unit pixel of an image sensor that senses both visible light and infrared light.

### DISCUSSION OF THE RELATED ART

An image sensor is a semiconductor device that senses and converts an incident light into an electrical signal. The image sensor may be employed in an electronic device such as a digital camera, a cellular phone, a smart phone, etc. The image sensor may include a charged coupled device (CCD) image sensor and a complementary metal-oxide semiconductor (CMOS) image sensor. The CMOS image sensor may be manufactured with a lower cost, may be integrated with peripheral circuits, and may have a lower power consumption compared to the CCD image sensor. In addition, an image sensor (e.g., a CMOS image sensor) capable of sensing infrared light has been developed for various applications such as iris recognition, tomography, a color image dynamic range enhancement, or the like.

For example, a back-side illuminated complementary metal-oxide-semiconductor (BSI CMOS) image sensor may be used for sensing the infrared light. In some instances, an amount of infrared light absorption of the BSI CMOS image sensor may be insufficient, and the BSI CMOS image sensor may not sense the infrared light enough to perform the intended functions (e.g., iris recognition, tomography, color image dynamic range (DR) enhancement, etc). If an area of an infrared light detection region of an image sensor (e.g., the BSI CMOS image sensor) is increased to increase an amount of infrared light absorption of the image sensor, resolution of the image sensor may be limited. In addition, if a thickness of an epitaxial layer of the image sensor is increased to increase an amount of infrared light absorption of the image sensor, the image sensor may not operate normally.

### SUMMARY

According to an exemplary embodiment of the present inventive concept, a unit pixel of an image sensor is provided. The unit pixel includes a visible light detection layer and an infrared detection layer. The infrared light detection layer is disposed on the visible light detection layer. The visible light detection layer includes visible light pixels and color filters configured to detect visible light to output first charges. The infrared light detection layer includes at least one infrared light pixel configured to detect infrared light to output second charges.

In an exemplary embodiment, the infrared light detection layer may include organic material.

In an exemplary embodiment, the organic material may include monomer material or low weight molecule material.

In an exemplary embodiment, the area of the at least one infrared light pixel may be at least 4× the area of one of the visible light pixels.

In an exemplary embodiment, each of the at least one infrared light pixel may include electrodes configured to receive a variable bias voltage to adjust rate of infrared light absorption.

In an exemplary embodiment, the unit pixel may further include a plurality of storage elements. Each of the plurality of storage elements may correspond to each infrared light pixel.

In an exemplary embodiment, the unit pixel may further include a single storage element for storing second charges.

In an exemplary embodiment, the infrared light detection layer may include one of a quantum dot or a III-V compound.

In an exemplary embodiment, the unit pixel may further include first signal generation circuit and second signal generation circuit. The first signal generation circuit may be configured to generate first signals corresponding to the first charges. The second signal generation circuit may be configured to generate second signals corresponding to the second charges.

In an exemplary embodiment, the unit pixel may further include a mode selection circuit to selectively activate one of the first and second signal generation circuits in single mode operation or activate both the first and second signal generation circuits in dual mode operation.

According to an exemplary embodiment of the present inventive concept, a unit pixel of an image sensor is provided. The unit pixel includes a stacked visible light detection layer, a green light detection layer, and an infrared light detection layer. The visible light detection layer includes visible light pixels and color filters. The green light detection layer is made of organic material and includes at least one green light pixel. Incident visible light including green light are detected by the visible light detection layer and the green light detection layer and converted to first charges. The infrared light detection layer includes at least one infrared light pixel configured to detect and convert infrared light to second charges.

In an exemplary embodiment, the color filters may be blue and red filters.

In an exemplary embodiment, the infrared light detection layer may be made of organic material.

In an exemplary embodiment, the organic material may include monomer material or low weight molecule material.

In an exemplary embodiment, the area of the at least one infrared light pixel may be at least 4× the area of each of the visible light pixels other than the green pixel.

In an exemplary embodiment, the area of the at least one green light pixel may be at least 4× the area of each of the visible light pixels.

In an exemplary embodiment, the organic material of the green light detecting layer includes monomer material or low weight molecule material.

In an exemplary embodiment, each of the at least one infrared light pixel may include electrodes configured to receive a variable bias voltage to adjust rate of infrared light absorption.

In an exemplary embodiment, the unit pixel may further include a plurality of storage elements. Each of the plurality of storage elements may correspond to each at least one infrared light pixel.

In an exemplary embodiment, the unit pixel may further include a single storage element for storing the second charges.

According to an exemplary embodiment of the present inventive concept, a unit pixel of an image sensor is provided. The unit pixel includes a stacked first visible light detection layer, a second visible light detection layer, a third visible light detection layer, and an infrared light detection layer. Each layer is of organic material and includes a light pixel. Visible light is detected by the light pixels of the first, second, and third visible light detection layers. Infrared light is detected by the infrared light pixel.

In an exemplary embodiment, the first visible light detection layer may be configured to detect red light. The second visible light detection layer may be configured to detect green light. The third visible light may be configured to detect blue light.

In an exemplary embodiment, the organic material may include monomer material or low weight molecule material.

In an exemplary embodiment, each of the light detecting pixels may include electrodes configured to receive a variable bias voltage to adjust rate of light absorption.

In an exemplary embodiment, the unit pixel may further include a plurality of storage elements. Each of the plurality of storage elements may correspond to each light pixel.

According to an exemplary embodiment of the present inventive concept, an electronic device is provided. The electronic device includes an image sensor. The image sensor includes a pixel array including a plurality of unit pixels and a controller. Each unit pixel includes a visible light detection layer, an infrared light detection layer disposed on the visible light detection layer, a plurality of storage elements, and a conversion unit. The visible light detection layer includes visible light pixels and color filters configured to detect visible light to output the first charges. The infrared light detection layer includes at least one infrared light pixel configured to detect infrared light to output the second charges. The plurality of storage elements is configured to store first charges and second charges. The conversion unit is configured to convert the stored first charges to first signals and to convert the stored second charges to second signals. The controller is configured to generate control signals to control the pixel array.

In an exemplary embodiment, the controller may be configured to generate mode selection signals including single mode wherein only visible light detection may be activated and dual mode wherein both visible light detection and infrared light detection may be activated.

In an exemplary embodiment, the mode selection may be based on a comparison of detected luminosity against a reference luminosity.

In an exemplary embodiment, dual mode may be selected when detected luminosity is below the reference luminosity.

In an exemplary embodiment, the device may further include a processor, a memory device, and at least one of a wired communication port or a wireless communication device.

In an exemplary embodiment, the memory device may include a volatile memory and a nonvolatile memory.

In an exemplary embodiment, the memory device may include at least one of a DRAM, a SRAM, a mobile DRAM, a PRAM, a RRAM, a NFGM, a PoRAM, a MRAM, or a FRAM.

In an exemplary embodiment, the electronic device may be embodied as a smart phone.

In an exemplary embodiment, the device may further include a camera serial interface (CSI) configured to interface with a CSI device.

In an exemplary embodiment, the electronic device may be embodied as a mobile computing device, a camera, a cell phone, a tablet, or a navigation device.

### BRIEF DESCRIPTION OF THE DRAWINGS

Exemplary embodiments of the present inventive concept will be more clearly understood from the following detailed description taken in conjunction with the accompanying drawings, in which:

FIG. 1 is a block diagram illustrating an image sensor according to an exemplary embodiment of the present inventive concept;

FIG. 2 is a diagram illustrating a unit pixel included in the image sensor of FIG. 1 according to an exemplary embodiment of the present inventive concept;

FIG. 3 is a cross-sectional view taken along A′-A″ line in FIG. 2;

FIG. 4 is a diagram illustrating a unit pixel included in the image sensor of FIG. 1 according to an exemplary embodiment of the present inventive concept;

FIG. 5 is a cross-sectional view taken along B′-B″ line in FIG. 4;

FIG. 6 is a diagram illustrating a unit pixel included in the image sensor of FIG. 1 according to an exemplary embodiment of the present inventive concept;

FIG. 7 is a cross-sectional view taken along C′-C″ line in FIG. 6;

FIG. 8 is a diagram illustrating a unit pixel included in the image sensor of FIG. 1 according to an exemplary embodiment of the present inventive concept;

FIG. 9 is a cross-sectional view taken along D′-D″ line in FIG. 8;

FIG. 10A is a circuit diagram of a sub-pixel of a unit pixel according to an exemplary embodiment of the present inventive concept;

FIG. 10B is a diagram illustrating the sub-pixel of FIG. 10A when the sub-pixel of FIG. 10A is a visible light detection pixel according to an exemplary embodiment of the present inventive concept;

FIG. 10C is a diagram illustrating the sub-pixel of FIG. 10A when the sub-pixel of FIG. 10A is an infrared light detection pixel according to an exemplary embodiment of the present inventive concept;

FIG. 11 is a flowchart illustrating an exemplary embodiment of the present inventive concept in which a first electrical signal and a second electrical signal are generated by a unit pixel included in the image sensor of FIG. 1;

FIG. 12 are circuit diagrams of signal generation circuits in respective sub-pixels of a unit pixel included in the image sensor of FIG. 1;

FIG. 13 is a flowchart illustrating an exemplary embodiment of the present inventive concept in which a first electrical signal and a second electrical signal are generated by a unit pixel included in the image sensor of FIG. 1;

FIG. 14 is a circuit diagram of a signal generation circuit that is shared by respective sub-pixels of a unit pixel according to an exemplary embodiment of the present inventive concept;

FIG. 15 is a diagram illustrating an operating mode of the image sensor of FIG. 1 according to an exemplary embodiment of the present inventive concept;

FIG. 16 is a diagram illustrating an exemplary embodiment of the present inventive concept in which a bias is applied to an infrared light detection pixel of a unit pixel included in the image sensor of FIG. 1;

FIG. 17 is a graph illustrating an exemplary embodiment of the present inventive concept in which an amount of infrared light absorption is adjusted based on a bias applied to an infrared light detection pixel of a unit pixel included in the image sensor of FIG. 1;

FIG. 18 is a flowchart illustrating an exemplary embodiment of the present inventive concept in which the image sensor of determines an operating mode based on external luminosity;

FIGS. 19 and 20 are graphs illustrating sensitivity of a unit pixel included in the image sensor of FIG. 1 is increased in a dual mode;

FIG. 21 is a flowchart illustrating a method of eliminating an infrared light noise for an image sensor according to an exemplary embodiment of the present inventive concept;

FIG. 22 is a diagram illustrating a pixel array of an image sensor employing the method of FIG. 21 according to an exemplary embodiment of the present inventive concept;

FIG. 23 is a diagram illustrating a filter structure of a unit pixel included in the pixel array of FIG. 22 according to an exemplary embodiment of the present inventive concept;

FIG. 24 is a graph illustrating an operation of a dual band-pass filter in the filter structure of FIG. 23 according to an exemplary embodiment of the present inventive concept;

FIG. 25A is a graph illustrating an operation of a visible light cut filter in the filter structure of FIG. 23 according to an exemplary embodiment of the present inventive concept;

FIG. 25B is a graph illustrating an operation of an infrared light cut filter in the filter structure of FIG. 23 according to an exemplary embodiment of the present inventive concept;

FIG. 26 is a block diagram illustrating an electronic device according to an exemplary embodiment of the present inventive concept;

FIG. 27 is a diagram illustrating an exemplary embodiment of the present inventive concept in which the electronic device of FIG. 26 is implemented as a smart phone;

FIG. 28 is a flowchart illustrating an exemplary embodiment of the present inventive concept in which infrared light is sensed by an image sensor included in the electronic device of FIG. 26;

FIG. 29 is a flowchart illustrating an exemplary embodiment of the present inventive concept in which infrared light is sensed by an image sensor included in the electronic device of FIG. 26; and

FIG. 30 is a block diagram illustrating an interface used in the electronic device of FIG. 26 according to an exemplary embodiment of the present inventive concept.

### DETAILED DESCRIPTION OF THE EMBODIMENTS

Various exemplary embodiments of the present inventive concept will be described more fully hereinafter with reference to the accompanying drawings. These exemplary embodiments of the present inventive concept are provided so that this disclosure will be thorough and complete, and will fully convey the scope of the present inventive concept to those skilled in the art. In the drawings, the dimensions and sizes of layers and regions may be exaggerated for clarity. Like numerals may refer to like elements throughout.

It will be understood that, although the terms first, second, third etc. may be used herein to describe various elements, these elements should not be limited by these terms. These terms are used to distinguish one element from another. As used herein, the term “and/or” includes any and all combinations of one or more of the associated listed items.

As used herein, the singular forms “a,” “an” and “the” are intended to include the plural forms as well, unless the context clearly indicates otherwise.

FIG. 1 is a block diagram illustrating an image sensor according to an exemplary embodiment of the present inventive concept.

Referring to FIG. 1, the image sensor 100 may include a pixel array 120, an analog to digital converter (ADC) unit 140, a digital signal processor (DSP) unit 160, and a controller 180 that controls the pixel array 120, the ADC unit 140, and the DSP unit 160.

The pixel array 120 may include a plurality of unit pixels 122, a plurality of row-lines, and a plurality of column-lines, where the row-lines and the column-lines are connected to the unit pixels 122. For example, since the row-lines are arranged to intersect the column-lines, the unit pixels 122 may be arranged in a matrix form in the pixel array 120. Here, each of the unit pixels 122 has a stacked structure in which an infrared light detection layer is stacked on a visible light detection layer, so that each of the unit pixels 122 may generate an image signal in a visible light band and an image signal in an infrared light band (e.g., a band having a wavelength longer than about 0.7 μm or a near-infrared light band without any crosstalk between the image signals. For example, each of the unit pixels 122 may have a structure in which a visible light detection pixel and an infrared light detection pixel are stacked on each other. In an exemplary embodiment, the pixel array 120 may include the row-lines and the column-lines for each of the visible light detection pixel and the infrared light detection pixel. In an exemplary embodiment, the pixel array 120 may include the row-lines and the column-lines shared by the visible light detection pixel and the infrared light detection pixel. The visible light detection pixel may include a photoelectric conversion unit and a signal generation circuit that generates an electrical signal corresponding to an accumulated amount of charges that are converted from incident visible light by the photoelectric conversion unit. For example, the photoelectric conversion unit of the visible light detection pixel may be a photoelectric conversion element (e.g., photodiode) or a combination of a visible light detection layer having a visible light detection material and a charge storage element that is connected to the visible light detection layer. In addition, the infrared light detection pixel may include a photoelectric conversion unit and a signal generation circuit that generates an electrical signal corresponding to an accumulated amount of charges that are converted from incident infrared light by the photoelectric conversion unit. For example, the photoelectric conversion unit of the infrared light detection pixel may be a combination of an infrared light detection layer having an infrared light detection material and a charge storage element that is connected to the infrared light detection layer. For example, the charges may be understood as “electric charges” hereinafter.

In an exemplary embodiment, the visible light detection pixel may include a signal generation circuit dedicated to the visible light detection pixel, and the infrared light detection pixel may include a signal generation circuit dedicated to the infrared light detection pixel. In this case, the visible light detection pixel may generate an electrical signal corresponding to an accumulated amount of charges that are converted from the incident visible light, and the infrared light detection pixel may generate an electrical signal corresponding to an accumulated amount of charges that are converted from the incident infrared light. Thus, the electrical signal corresponding to the incident visible light and the electrical signal corresponding to the incident infrared light may be concurrently or sequentially generated. In an exemplary embodiment, the visible light detection pixel and the infrared light detection pixel may share a signal generation circuit. In this case, the visible light detection pixel and the infrared light detection pixel may sequentially generate an electrical signal corresponding to an accumulated amount of charges that are converted from the incident visible light and an electrical signal corresponding to an accumulated amount of charges that are converted from the incident infrared light.

As described above, each of the unit pixels 122 may have a stacked structure in which an infrared light detection layer is stacked on a visible light detection layer. In an exemplary embodiment, each of the unit pixels 122 may include a visible light detection layer and an infrared light detection layer. The visible light detection layer may include a color filter layer and a silicon layer. The infrared light detection layer may be stacked on the visible light detection layer. The visible light detection layer may convert incident visible light input through the color filter layer into first charges based on a photoelectric conversion element formed in the silicon layer. For example, the photoelectric conversion element may be a photodiode. The infrared light detection layer may include an infrared light detection material between an upper electrode and a lower electrode. The infrared light detection layer may convert incident infrared light into second Charges based on the infrared light detection material. For example, the infrared light detection material may include at least one of an organic material, a quantum dot, a III-V compound, or the like. For example, the organic material may include monomer material or low weight molecule material. The silicon layer may include a charge storage element that is electrically connected to the infrared light detection layer via the color filter layer. For example, the charge storage element may be arranged near the photoelectric conversion element. For example, the charge storage element may be an (n+)-type doping region formed in a (p)-type silicon region. In an exemplary embodiment, each of the unit pixels 122 may further include a micro-lens layer that guides the incident infrared light and the incident visible light into the infrared light detection layer and the visible light detection layer, respectively. For example, the micro-lens layer may be disposed on the infrared light detection layer. In an exemplary embodiment, the image sensor may employ a Bayer pattern technology. In this case, the color filter layer may include first through third color filters, and the first through third color filters of the color filter layer may be arranged in a Bayer pattern shape. In an exemplary embodiment, the first color filter may correspond to a green color filter, the second color filter may correspond to a red color filter, and the third color filter may correspond to a blue color filter. In an exemplary embodiment, the first color filter may correspond to a magenta color filter, the second color filter may correspond to a yellow color filter, and the third color filter may correspond to a cyan color filter.

In an exemplary embodiment, each of the unit pixels 122 may include a first visible light detection layer that includes a color filter layer and a silicon layer, a second visible light detection layer that is stacked on the first visible light detection layer, and an infrared light detection layer that is stacked on the second visible light detection layer. The first visible light detection layer may convert first incident visible light input through the color filter layer into first charges based on a photoelectric conversion element formed in the silicon layer. For example, the photoelectric conversion element may be a photodiode. The second visible light detection layer may include a visible light detection material between an upper electrode and a lower electrode. The second visible light detection layer may convert second incident visible light into second charges based on the visible light detection material. For example, the visible light detection material may include at least one of an organic material, a quantum dot, a III-V compound or the like. For example, the organic material may include monomer material or low weight molecule material. The infrared light detection layer may include an infrared light detection material between an upper electrode and a lower electrode. The infrared light detection layer may convert incident infrared light into third charges based on the infrared light detection material. For example, the infrared light detection material may include at least one of an organic material, a quantum dot, a III-V compound, or the like. Here, the silicon layer may include a first charge storage element and a second charge storage element. The first charge storage may be electrically connected to the second visible light detection layer via the color filter layer. The second charge storage element may be electrically connected to the infrared light detection layer via the color filter layer and the second visible light detection layer. For example, each of the first charge storage element and the second charge storage element may be an (n+)-type doping region formed in a (p)-type silicon region. In an exemplary embodiment, each of the unit pixels 122 may further include a micro-lens layer that guides the incident infrared light, the first incident visible light, and the second incident visible light into the infrared light detection layer, the first visible light detection layer, and the second visible light detection layer, respectively. For example, the micro-lens layer may be disposed on the infrared light detection layer.

In an exemplary embodiment, each of the unit pixels 122 may include a first visible light detection layer, a second visible light detection layer that is stacked on the first visible light detection layer, a third visible light detection layer that is stacked on the second visible light detection layer, an infrared light detection layer that is stacked on the third visible light detection layer, and a silicon layer. The first visible light detection layer may include a first visible light detection material between an upper electrode and a lower electrode. The first visible light detection layer may convert first incident visible light into first charges based on the first visible light detection material. For example, the first visible light detection material may include at least one of an organic material, a quantum dot, a III-V compound, or the like. The second visible light detection layer may include a second visible light detection material between an upper electrode and a lower electrode. The second visible light detection layer may convert second incident visible light into second charges based on the second visible light detection material. For example, the second visible light detection material may include at least one of an organic material, a quantum dot, a III-V compound, or the like. The third visible light detection layer may include a third visible light detection material between an upper electrode and a lower electrode. The third visible light detection layer may convert third incident visible light into third charges based on the third visible light detection material. For example, the third visible light detection material may include at least one of an organic material, a quantum dot, a III-V compound, or the like. For example, the organic material may include monomer material or low weight molecule material. The infrared light detection layer may include an infrared light detection material between an upper electrode and a lower electrode. The infrared light detection layer may convert incident infrared light into fourth charges based on the infrared light detection material. For example, the first visible light detection material may include at least one of an organic material, a quantum dot, a III-V compound, or the like. For example, the organic material may include monomer material or low weight molecule material. The silicon layer may include first through fourth charge storage elements. The first charge storage element may be electrically connected to the first visible light detection layer, the second charge storage element may be electrically connected to the second visible light detection layer via the first visible light detection layer, the third charge storage element may be electrically connected to the third visible light detection layer via the first and second visible light detection layers, and the fourth charge storage element may be electrically connected to the infrared light detection layer via the first through third visible light detection layers. For example, each of the first charge storage element, the second charge storage element, the third charge storage element, and the fourth Charge storage element may be an (n+)-type doping region formed in a (p)-type silicon region. In an exemplary embodiment, each of the unit pixels 122 may further include a micro-lens layer that guides the incident infrared light, the first incident visible light, the second incident visible light, and the third incident visible light into the infrared light detection layer, the first visible light detection layer, the second visible light detection layer, and the third visible light detection layer, respectively. For example, the micro-dens layer may be disposed on the infrared light detection layer.

The ADC unit 140 may convert an analog signal to a digital signal, where the analog signal corresponds to an electrical signal output from the pixel array 120. To this end, the ADC unit 140 may include a plurality of analog to digital converters. The ADC unit 140 may convert an electrical signal corresponding to an accumulated amount of charges that are converted from the incident visible light (e.g., a first analog signal) into a first digital signal, and may convert an electrical signal corresponding to an accumulated amount of charges that are converted from the incident infrared light (e.g., a second analog signal) into a second digital signal. In an exemplary embodiment, the ADC unit 140 may sequentially convert the first analog signal corresponding to the incident visible light and the second analog signal corresponding to the incident infrared light into the first digital signal and the second digital signal, respectively (e.g., referred to as a sequential ADC. In an exemplary embodiment, the ADC unit 140 may include a first ADC unit and a second ADC unit. The first ADC unit may convert a first analog signal corresponding to an accumulated amount of charges that are converted from the incident visible light into a first digital signal. The second ADC unit may convert a second analog signal corresponding to an accumulated amount of charges that are converted from the incident infrared light into a second digital signal. For example, the first ADC unit and the second ADC unit may generate the first digital signal and the second digital signal, respectively (e.g., referred to as a parallel ADC). In an exemplary embodiment, the ADC unit 140 may include a correlated double sampling (CDS) unit that extracts an effective signal component. In an exemplary embodiment, the CDS unit may perform an analog correlated double sampling operation by which an effective signal component is extracted based on a difference between a reset output signal corresponding to a reset component and an analog signal corresponding to a signal component. In an exemplary embodiment, the CDS unit may perform a digital correlated double sampling operation by which the reset output signal and the analog signal are converted into digital signals, and a difference between the digital signals is extracted as an effective signal component. In an exemplary embodiment, the CDS unit may perform a dual correlated double sampling operation. For example, the CDS unit may perform both the analog correlated double sampling operation and the digital correlated double sampling operation.

The DSP unit 160 may perform a digital signal processing on the digital signal to generate an image signal. For example, the DSP unit 160 may receive the digital signal from the ADC unit 140 and may perform the digital signal processing on the digital signal. For example, the DSP unit 160 may perform an image interpolation, a color correction, a white balance correction, a gamma correction, a color conversion, etc. In an exemplary embodiment, a digital signal output from the ADC unit 140 may be amplified by an amplifying circuit, and then may be provided to the DSP unit 160. In an exemplary embodiment, the DSP unit 160 may generate a first image signal by performing a digital signal processing on a first digital signal corresponding to an accumulated amount of charges that are converted from the incident visible light and may generate a second image signal by performing a digital signal processing on a second digital signal corresponding to an accumulated amount of charges that are converted from the incident infrared light. For example, the DSP unit 160 may individually generate the first image signal and the second image signal. In this case, the second image signal output from the image sensor 100 may be used in a specific application (e.g., iris recognition, etc). In an exemplary embodiment, the DSP unit 160 may compensate a first digital signal corresponding to an accumulated amount of charges that are converted from the incident visible light based on a second digital signal corresponding to an accumulated amount of charges that are converted from the incident infrared light. For example, the DSP unit 160 may eliminate infrared light noises from the first digital signal corresponding to the accumulated amount of charges that are converted from the incident visible light based on the second digital signal corresponding to the accumulated amount of charges that are converted from the incident infrared light. For example, the DSP unit 160 may increase a quality of an image output from the image sensor 100 by compensating the first digital signal corresponding to the accumulated amount of charges that are converted from the incident visible light based on the second digital signal corresponding to the accumulated amount of charges that are converted from the incident infrared light. Although it is illustrated in FIG. 1 that the DSP unit 160 is included in the image sensor 100, the DSP unit 160 may be external to the image sensor 100.

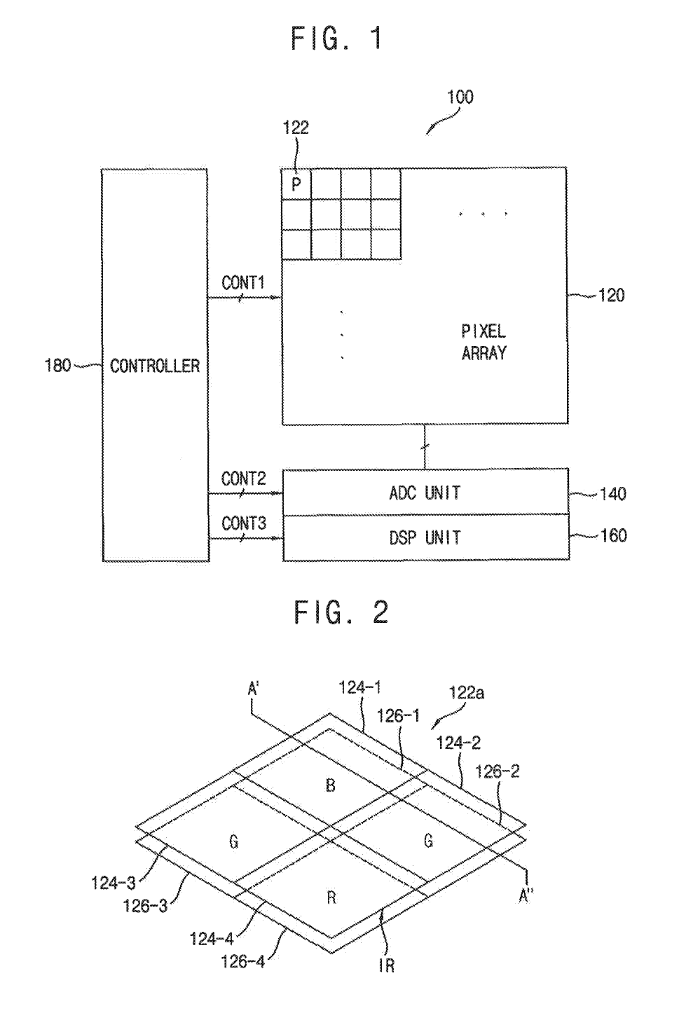

The controller 180 may control the pixel array 120, the ADC unit 140, and the DSP unit 160 through, for example, first through third control lines CONT1, CONT2, and CONT3, respectively. Thus, the controller 180 may generate various signals such as a clock signal, a timing control signal, etc to operate the pixel array 120, the ADC unit 140, and the DSP unit 160, respectively. For example, the controller 180 may include a vertical scanning circuit for controlling row addressing and row scanning operations of the pixel array 120, a horizontal scanning circuit for controlling column addressing and column scanning operations of the pixel array 120, a voltage generating circuit for generating a plurality of voltages used in the ADC unit 140 (e.g., a logic control circuit, a phase locked loop (PLL) circuit, a timing control circuit, a communication interface circuit, etc), etc. As described above, the image sensor 100 includes the unit pixels 122 each having a stacked structure in which the infrared light detection layer is stacked on the visible light detection layer. Thus, the image sensor 100 provides a high-quality image (e.g., a high-quality visible light image and/or a high-quality infrared light image). Hereinafter, a structure of each unit pixel 122 included in the image sensor 100 will be described in detail with reference to FIGS. 2 through 9.

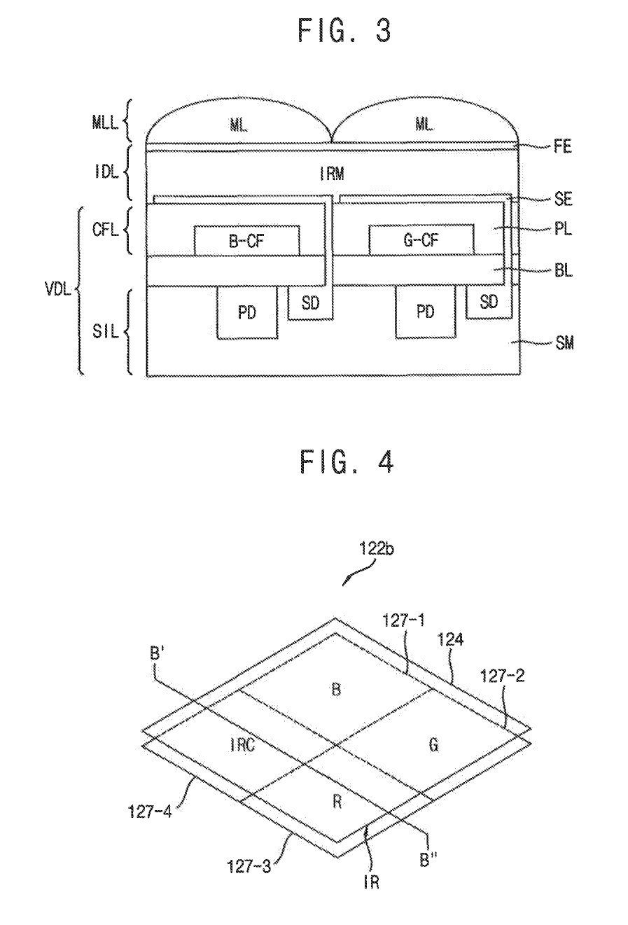

FIG. 2 is a diagram illustrating a unit pixel included in the image sensor of FIG. 1 according to an exemplary embodiment of the present inventive concept. FIG. 3 is a cross-sectional view taken along A′-A″ line in FIG. 2.

Referring to FIGS. 2 and 3, a unit pixel 122a included in the image sensor 100 is illustrated. The unit pixel 122a may include a visible light detection layer VDL and an infrared light detection layer IDL that is stacked on the visible light detection layer VDL. Here, as illustrated in FIG. 2, the unit pixel 122a may include first through fourth plane regions.

Referring to FIG. 3, the unit pixel 122a in the image sensor 100 according to an exemplary embodiment of the present inventive concept may have a stacked structure in which the infrared light detection layer IDL is stacked on the visible light detection layer VDL and the infrared light detection layer IDL may include at least one of an organic material, a quantum dot, a III-V compound, or the like, which may increase photoelectric conversion efficiency in the infrared light band. In addition, first through third color filters of a color filter layer CFL included in the visible light detection layer VDL may be arranged in a Bayer pattern shape. Thus, since the existence of the infrared light detection layer IDL does not have any influence (e.g., reduction in area, etc) on the visible light detection layer VDL in the unit pixel 122a, the unit pixel 122a may generate an image signal in a visible light band and an image signal in an infrared light band without any crosstalk between the image signals. Thus, the unit pixel 122a may maximize (or increase) a light receiving area of the image sensor 100 based on a stacked structure in which the infrared light detection layer IDL is stacked on the visible light detection layer VDL, and thus, the image sensor 100 may output a visible light image having a high resolution and an infrared light image having a high resolution. Further, since the infrared light detection layer IDL absorbs incident infrared light over the visible light detection layer VDL, the infrared light detection layer IDL may function as an infrared light (IR) cut filter for the visible light detection layer VDL in the unit pixel 122a. Thus, the unit pixel 122a according to an exemplary embodiment of the present inventive concept may not include an additional IR cut filter for the visible light detection layer VDL.

The visible light detection layer VDL may include a color filter layer CFL and a silicon layer SIL. The visible light detection layer VDL may convert incident visible light input through the color filter layer CFL into first charges based on a photoelectric conversion element PD formed in the silicon layer SIL. For example, the photoelectric conversion element PD may be a photodiode. As illustrated in FIG. 3, an insulation layer BL may be disposed on the silicon layer SIL, and the color filter layer CFL may be disposed on the insulation layer BL in the visible light detection layer VDL. For example, the insulation layer BL may include oxide, or may include oxide and nitride. In addition, the color filter layer CFL may include color filters B-CF (e.g., blue color filter) and G-CF (e.g., green color filter) and a planarization layer PL that is disposed on the color filters B-CF and G-CF. For example, the planarization layer PL may include acrylic or epoxy material. A structure of the visible light detection layer VDL of the present inventive concept is not limited to a structure illustrated in FIG. 3. The visible light detection layer VDL may include a first color filter visible light detection region that detects the incident visible light input through a first color filter of the color filter layer CFL, a second color filter visible light detection region that detects the incident visible light input through a second color filter of the color filter layer CFL, and a third color filter visible light detection region that detects the incident visible light input through a third color filter of the color filter layer CFL. Here, the first color filter visible light detection region may be arranged in two plane regions of the first through fourth plane regions of the unit pixel 122a, the second color filter visible light detection region may be arranged in one plane region of the first through fourth plane regions of the unit pixel 122a, and the third color filter visible light detection region may be arranged in one plane region of the first through fourth plane regions of the unit pixel 122a. For example, referring to FIG. 2 and FIG. 3, the visible light detection layer VDL may include a blue color light detection region 126-1 that detects the incident visible light (e.g., blue color light) input through a blue color filter of the color filter layer CFL, green color light detection regions 126-2 and 126-3 that detect the incident visible light (e.g., green color light) input through a green color filter of the color filter layer CFL, and a red color light detection region 126-4 that detects the incident visible light (e.g., red color light) input through a red color filter of the color filter layer CFL. For example, the green color light detection regions 126-2 and 126-3 may be the first color filter visible light detection region, and the blue color light detection region 126-1 and the red color light detection region 126-4 may be the second color filter visible light detection region and the third color filter visible light detection region, respectively. Since human's eyes are more sensitive to a green color compared to other colors (e.g., red color and blue color), it is illustrated in FIG. 2 that the green color light detection regions 126-2 and 126-3 occupy 50% of an area of the unit pixel 122a, the blue color light detection region 126-1 occupies 25% of the area of the unit pixel 122a, and the red color light detection region 126-4 occupies 25% of the area of the unit pixel 122a. However, an arrangement of the first through third color filter visible light detection regions included in the visible light detection layer VDL of the present inventive concept is not limited thereto.

The infrared light detection layer IDL may be stacked on the visible light detection layer VDL. The infrared light detection layer IDL may include an infrared light detection material IRM between an upper electrode FE and a lower electrode SE. The infrared light detection layer IDL may convert incident infrared light into second charges based on the infrared light detection material IRM. For example, the infrared light detection material IRM may include at least one of an organic material, a quantum dot, a III-V compound, or the like. For example, the organic material may include monomer material or low weight molecule material. In an exemplary embodiment, an amount of infrared light absorption of the infrared light detection layer IDL may be adjusted based on a bias that is generated by a first voltage applied to the upper electrode FE and a second voltage applied to the lower electrode SE. As illustrated in FIG. 2, the infrared light detection layer IDL may include a first infrared light detection region 124-1, a second infrared light detection region 124-2, a third infrared light detection region 124-3, and a fourth infrared light detection region 124-4. In addition, the first through fourth infrared light detection regions 124-1, 124-2, 124-3, and 124-4 may be arranged in the first through fourth plane regions of the unit pixel 122a, respectively. For example, the first infrared light detection region 1244 may be arranged in the first plane region of the unit pixel 122a, and may be arranged on the blue color light detection region 126-1. The second infrared light detection region 124-2 may be arranged in the second plane region of the unit pixel 122a, and may be arranged on the green color light detection region 126-2. The third infrared light detection region 124-3 may be arranged in the third plane region of the unit pixel 122a, and may be arranged on the green color light detection region 126-3. The fourth infrared light detection region 124-4 may be arranged in the fourth plane region of the unit pixel 122a, and may be arranged on the red color light detection region 126-4. The silicon layer SIL may include a charge storage element SD that is electrically connected to the infrared light detection layer IDL via the color filter layer CFL. For example, the charge storage element SD may be arranged near the photoelectric conversion element PD. For example, the charge storage element SD may be an (n+)-type doping region formed in a (p)-type silicon region SM. As illustrated in FIG. 3, when the infrared light detection layer IDL includes the first infrared light detection region 124-1, the second infrared light detection region 124-2, the third infrared light detection region 124-3, and the fourth infrared light detection region 124-4, the charge storage element SD may be arranged in each of the first through fourth plane regions of the unit pixel 122a (e.g., the charge element SI) may be distributed to the first through fourth plane regions of the unit pixel 122a) and electrically connected to each of the first infrared light detection region 124-1, the second infrared light detection region 124-2, the third infrared light detection region 124-3, and the fourth infrared light detection region 124-4.

In an exemplary embodiment, the silicon layer SIL may include a first signal generation circuit that is connected to the photoelectric conversion element PD and a second signal generation circuit that is connected to the charge storage element SD. The first signal generation circuit may generate a first electrical signal corresponding to an accumulated amount of the first charges that are converted from the incident visible light. The second signal generation circuit may generate a second electrical signal corresponding to an accumulated amount of the second charges that are converted from the incident infrared light. In this case, the first signal generation circuit and the second signal generation circuit may concurrently or sequentially generate the first electrical signal and the second electrical signal, respectively. In an exemplary embodiment, the silicon layer SIL may include a signal generation circuit that is connected to the photoelectric conversion element PD and the charge storage element SD. The signal generation circuit may sequentially generate a first electrical signal corresponding to an accumulated amount of the first Charges that are converted from the incident visible light and a second electrical signal corresponding to an accumulated amount of the second charges that are converted from the incident infrared light. In this case, the signal generation circuit may generate the first electrical signal, and then may generate the second electrical signal. Alternatively, the signal generation circuit may generate the second electrical signal, and then may generate the first electrical signal.

In an exemplary embodiment, the unit pixel 122a may further include a micro-lens layer MLL that guides the incident infrared light and the incident visible light into the infrared light detection layer IDL and the visible light detection layer VDL, respectively. Here, the micro-lens layer MLL may include a plurality of micro-lenses ML. For example, the micro-lens layer MLL may be disposed on the infrared light detection layer IDL. In an exemplary embodiment, when guiding the incident infrared light to the infrared light detection layer IDL is not required in the unit pixel 122a, the micro-lens layer MLL may be disposed under the infrared light detection layer IDL. As described above, since the unit pixel 122a has a stacked structure in which the infrared light detection layer IDL is stacked on the visible light detection layer VDL, the image sensor 100 may output a visible light image having a high resolution (e.g., a high-quality visible light image) and an infrared light image having a high resolution (e.g., a high-quality infrared light image). For example, a unit pixel according to the related art may have a non-stacked structure and include one infrared light detection region, one red color light detection region, one green color light detection region, and one blue color light detection region. As illustrated in FIGS. 2 and 3, according to an exemplary embodiment of the present inventive concept, the unit pixel 122a may have a stacked structure and includes four infrared light detection regions, one red color light detection region, two green color light detection regions, and one blue color light detection region. Accordingly, the unit pixel 122a according to an exemplary embodiment of the present inventive concept may generate more image-information than a unit pixel having a non-stacked structure.

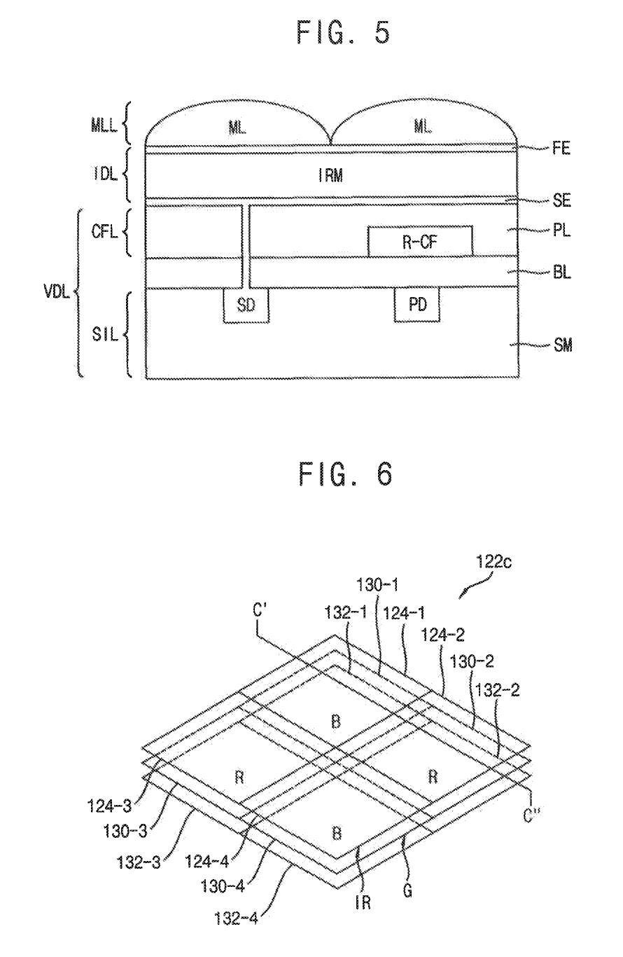

FIG. 4 is a diagram illustrating a unit pixel included in the image sensor of FIG. 1 according to an exemplary embodiment of the present inventive concept. FIG. 5 is a cross-sectional view taken along B′-B″ line in FIG. 4.

Referring to FIGS. 4 and 5, a unit pixel 122b included in the image sensor 100 is illustrated. The unit pixel 122b may include a visible light detection layer VDL and an infrared light detection layer IDL that is stacked on the visible light detection layer VDL. Here, as illustrated in FIG. 4, the unit pixel 122b may include first through fourth plane regions.

The visible light detection layer VDL may include a color filter layer CFL and a silicon layer SIL. The visible light detection layer VDL may convert incident visible light input through the color filter layer CFL into first charges based on a photoelectric conversion element PD formed in the silicon layer SIL. For example, the photoelectric conversion element PI) may be a photodiode. As illustrated in FIG. 5, an insulation layer BL may be disposed on the silicon layer SIL, and the color filter layer CFL may be disposed on the insulation layer BL in the visible light detection layer VDL. For example, the insulation layer BL may include oxide, or may include oxide and nitride. In addition, the color filter layer CFL may include a color filter R-CF and a planarization layer PI, that is disposed on the color filters R-CF. For example, the planarization layer PL may include acrylic or epoxy material. A structure of the visible light detection layer VDL of the present inventive concept is not limited to a structure illustrated in FIG. 5. The visible light detection layer VDL may include a first color filter visible light detection region that detects the incident visible light input through a first color filter of the color filter layer CFL, a second color filter visible light detection region that detects the incident visible light input through a second color filter of the color filler layer CM, and a third color filter visible light detection region that detects the incident visible light input through a third color filter of the color filter layer CFL. Here, the first color filter visible light detection region may be arranged in one plane region of the first through fourth plane regions of the unit pixel. 122b, the second color filter visible light detection region may be arranged in one plane region of the first through fourth plane regions of the unit pixel 122b, and the third color filter visible light detection region may be arranged in one plane region of the first through fourth plane regions of the unit pixel 122h. For example, as illustrated in FIG. 4, the visible light detection layer VDL may include a blue color light detection region 127-1 that detects the incident visible light (e.g., blue color light) input through a blue color filter of the color filter layer CFL, a green color light detection region 127-2 that detects the incident visible light (e.g., green color light) input through a green color filter of the color filter layer GEL, and a red color light detection region 127-3 that detects the incident visible light (e.g., red color light) input through a red color filter of the color filter layer CFL. For example, the blue color light detection region 127-1, the green color light detection region 127-2, and the red color light detection region 127-3 may be the first color filter visible light detection region, the second color filter visible light detection region, and the third color filter visible light detection region, respectively. However, an arrangement of the first through third color filter visible light detection regions included in the visible light detection layer VDL of the present inventive concept is not limited thereto.

Referring to FIG. 5, the infrared light detection layer IDL may be stacked on the visible light detection layer VDL. The infrared light detection layer IDL may include an infrared light detection material IRM between an upper electrode FE and a lower electrode SE. The infrared light detection layer IDL may convert incident infrared light into second charges based on the infrared light detection material IRM. For example, the infrared light detection material IRM may include at least one of an organic material, a quantum dot, a MN compound, or the like. For example, the organic material may include monomer material or low weight molecule material. In an exemplary embodiment, an amount of infrared light absorption of the infrared light detection layer IDL may be adjusted based on a bias that is generated by a first voltage applied to the upper electrode FE and a second voltage applied to the lower electrode SE. As illustrated in FIG. 4, the infrared light detection layer IDL may include one infrared light detection region 124, and the infrared light detection region IDL may be arranged in an entire region of the first through fourth plane regions of the unit pixel 122b. The silicon layer SIL may include a charge storage element SD that is electrically connected to the infrared light detection layer IDL via the color filter layer CFL. For example, the charge storage element SD may be arranged near the photoelectric conversion element PD. For example, the charge storage element SD may be an (n+)-type doping region formed in a (p)-type silicon region SM. As illustrated in FIG. 4, when the infrared light detection layer IDL includes one infrared light detection region 124, the charge storage element SD may be arranged in one plane region of the first through fourth plane regions of the unit pixel 122b, and electrically connected to the infrared light detection region 124. In this case, for example, a size of the charge storage element SD may be relatively large, and thus, the charge storage element SD may store the second charges generated by the infrared light detection region 124 that have an area corresponding the entire area of the unit pixel 122b. Thus, one plane region of the first through fourth plane regions of the unit pixel 122b is assigned to the charge storage element SD. For example, the one plane region assigned to the charge storage element SD of the first through fourth plane regions of the unit pixel 122b may be referred to as a dedicated region 127-4 for the charge storage element SD (e.g., indicated as IRC). In an exemplary embodiment, the silicon layer SIL may include a first signal generation circuit that is connected to the photoelectric conversion element PD and a second signal generation circuit that is connected to the charge storage element SD. The first signal generation circuit may generate a first electrical signal corresponding to an accumulated amount of the first charges that are converted from the incident visible light. The second signal generation circuit may generate a second electrical signal corresponding to an accumulated amount of the second charges that are converted from the incident infrared light. In an exemplary embodiment, the silicon layer SIL may include a signal generation circuit that is connected to the photoelectric conversion element PD and the charge storage element SD. The signal generation circuit may sequentially generate a first electrical signal corresponding to an accumulated amount of the first charges that are converted from the incident visible light and a second electrical signal corresponding to an accumulated amount of the second charges that are converted from the incident infrared light.

In an exemplary embodiment, the unit pixel 122b may further include a micro-lens layer MLL that guides the incident infrared light and the incident visible light into the infrared light detection layer IDL and the visible light detection layer VDL, respectively. Here, the micro-lens layer MLL may include a plurality of micro-lenses ML. For example, the micro-lens layer MLL may be disposed on the infrared light detection layer IDL. In an exemplary embodiment, when guiding the incident infrared light to the infrared light detection layer IDL is not required in the unit pixel 122h, the micro-lens layer MLL may be disposed under the infrared light detection layer IDL. As described above, since the unit pixel 122b has a stacked structure in which the infrared light detection layer IDL is stacked on the visible light detection layer VDL, the unit pixel 122b may generate an image signal in a visible light band and an image signal in an infrared light band without crosstalk between the image signals. In addition, since the unit pixel 122b has a stacked structure in which the infrared light detection layer IDL is stacked on the visible light detection layer VDL, the existence of the infrared light detection layer IDL does not have any influence (e.g., reduction in area, etc) on the visible light detection layer VDL in the unit pixel 122b. Thus, the image sensor 100 may output a visible light image having a high resolution and an infrared light image having a high resolution. Further, since the infrared light detection layer IDL absorbs a lot of infrared light over the visible light detection layer VDL, the infrared light detection layer IDL may function as an IR cut filter for the visible light detection layer VDL in the unit pixel 122b. Thus, the unit pixel 122b according to an exemplary embodiment of the present inventive concept may not include an additional IR cut filter for the visible light detection layer VDL.

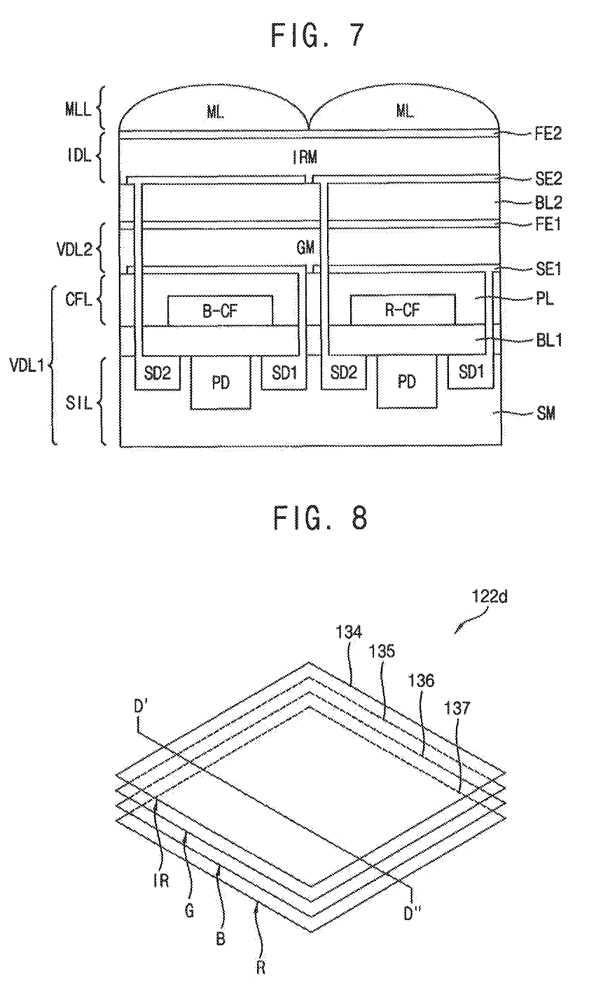

FIG. 6 is a diagram illustrating a unit pixel included in the image sensor of FIG. 1 according to an exemplary embodiment of the present inventive concept. FIG. 7 is a cross-sectional view taken along C′-C″ line in FIG. 6.

Referring to FIGS. 6 and 7, a unit pixel 122c included in the image sensor 100 is illustrated. The unit pixel 122c may include a first visible light detection layer VDL1, a second visible light detection layer VDL2 that is stacked on the first visible light detection layer VDL1, and an infrared light detection layer IDL that is stacked on the second visible light detection layer VDL2. Here, as illustrated in FIG. 6, the unit pixel 122c may include first through fourth plane regions.

The first visible light detection layer VDL1 may include a color filter layer CFL and a silicon layer SIL. The first visible light detection layer VDL1 may convert first incident visible light input through the color filter layer CFL into first charges based on a photoelectric conversion element PD formed in the silicon layer SIL. For example, the photoelectric conversion element PD may be a photodiode. As illustrated in FIG. 7, a first insulation layer BL1 may be disposed on the silicon layer SIL, and the color filter layer CFL may be disposed on the first insulation layer BL1 in the first visible light detection layer VDL1. For example, the insulation layer BL1 may include oxide, or may include oxide and nitride. In addition, the color filter layer CFL may include color filters B-CF and R-CF and a planarization layer PL that is disposed on the color filters B-CF and R-CF. For example, the planarization layer PL may include acrylic or epoxy material. A structure of the first visible light detection layer VDL1 of the present inventive concept is not limited to a structure illustrated in FIG. 7. The first visible light detection layer VDL1 may include a first color filter visible light detection region that detects the first incident visible light input through a first color filter of the color filter layer CFL and a second color filter visible light detection region that detects the first incident visible light input through a second color filter of the color filter layer CFL. Here, the first color filter visible light detection region may be arranged in two plane regions of the first through fourth plane regions of the unit pixel 122c, and the second color filter visible light detection region may be arranged in two plane regions of the first through fourth plane regions of the unit pixel 122c. For example, as illustrated in FIG. 7, the first visible light detection layer VDL1 may include blue color light detection regions 132-1 and 132-4 that detect the first incident visible light (e.g., blue color light) input through a blue color filter of the color filter layer CFL and red color light detection regions 132-2 and 132-3 that detect the first incident visible light (e.g., red color light) input through a red color filter of the color filter layer CFL. For example, the blue color light detection regions 132-1 and 132-4 and the red color light detection regions 132-2 and 132-3 may be the first color filter visible light detection region and the second color filter visible light detection region, respectively. However, an arrangement of the first and second color filter visible light detection regions included in the first visible light detection layer VDL1 of the present inventive concept is not limited thereto.

The second visible light detection layer VDL2 may be stacked on the first visible light detection layer VDU. The second visible light detection layer VDL2 may include a visible light detection material GM (e.g., a green light detection material) between an upper electrode FE1 and a lower electrode SE1. The second visible light detection layer VDL2 may convert second incident visible light into second charges based on the visible light detection material GM. For example, the visible light detection material GM may include at least one of an organic material, a quantum dot, a III-V compound, or the like. For example, the organic material may include monomer material or low weight molecule material. In an exemplary embodiment, an amount of visible light absorption of the second visible light detection layer VDL2 may be adjusted based on a bias that is generated by a first voltage applied to the upper electrode FE1 and a second voltage applied to the lower electrode SE1. As illustrated in FIG. 6, the second visible light detection layer VDL2 may include a first non-color filter visible light detection region 130-1, a second non-color filter visible light detection region 130-2, a third non-color filter visible light detection region 130-3, and a fourth non-color filter visible light detection region 130-4. Here, the first through fourth non-color filter visible light detection regions 130-1, 130-2, 130-3 and 130-4 may be arranged in the first through fourth plane regions of the unit pixel 122c, respectively. For example, each of the first through fourth non-color filter visible light detection regions 130-1, 130-2, 130-3 and 130-4 may not include a color filter. The silicon layer SIL may include a first charge storage element SD1 that is electrically connected to the second visible light detection layer VDL2 via the color filter layer CFL. For example, the first charge storage element SD1 may be arranged near the photoelectric conversion element PD. For example, the first charge storage element SD1 may be an (n+)-type doping region formed in a (p)-type silicon region SM. As illustrated in FIG. 6, when the second visible light detection layer VDL2 includes the first non-color filter visible light detection region 130-1, the second non-color filter visible light detection region 130-2, the third non-color filter visible light detection region 130-3, and the fourth non-color filter visible light detection region 130-4, the first charge storage element SD1 may be arranged in each of the first through fourth plane regions of the unit pixel 122c (e.g., the first charge storage element SD1 may be distributed to the first through fourth plane regions of the unit pixel 122c) and electrically connected to each of the first non-color filter visible light detection region 130-1, the second non-color filter visible light detection region 130-2, the third non-color filter visible light detection region 130-3, and the fourth non-color filter visible light detection region 130-4.

The infrared light detection layer IDL may be stacked on the second visible light detection layer VDL2. A second insulation layer BL2 may be disposed between the infrared light detection layer IDL and the second visible light detection layer VDL2. For example, the second insulation layer BL2 may include oxide, or may include oxide and nitride. The infrared light detection layer IDL may include an infrared light detection material IRM between an upper electrode FE2 and a lower electrode SE2. The infrared light detection layer IDL may convert incident infrared light into third charges based on the infrared light detection material. IRM. For example, the infrared light detection material IRM may include at least one of an organic material, a quantum dot, a III-V compound, or the like. For example, the organic material may include monomer material or low weight molecule material. In an exemplary embodiment, an amount of infrared light absorption of the infrared light detection layer IDL may be adjusted based on a bias that is generated by a first voltage applied to the upper electrode FE2 and a second voltage applied to the lower electrode SE2. As illustrated in FIG. 6, the infrared light detection layer IDL may include a first infrared light detection region 124-1, a second infrared light detection region 124-2, a third infrared light detection region 124-3, and a fourth infrared light detection region 124-4. In addition, the first through fourth infrared light detection regions 124-1, 124-2, 124-3, and 124-4 may be arranged in the first through fourth plane regions of the unit pixel 122c, respectively. For example, the first infrared light detection region 124-1 may be arranged in the first plane region of the unit pixel 122c, the second infrared light detection region 124-2 may be arranged in the second plane region of the unit pixel 122c, the third infrared light detection region 124-3 may be arranged in the third plane region of the unit pixel 122c, and the fourth infrared light detection region 124-4 may be arranged in the fourth plane region of the unit pixel 122c. The silicon layer SIL may include a second charge storage element SD2 that is electrically connected to the infrared light detection layer IDL via the color filter layer CFL and the second visible light detection layer VDL2. For example, the second charge storage element SD2 may be arranged near the photoelectric conversion element PD. For example, the second charge storage element SD2 may be an (n+)-type doping region formed in a (p)-type silicon region SM. As illustrated in FIG. 6, when the infrared light detection layer IDL includes the first infrared light detection region 124-1, the second infrared light detection region 124-2, the third infrared light detection region 124-3, and the fourth infrared light detection region 124-4, the second charge storage element SD2 may be arranged in each of the first through fourth plane regions of the unit pixel 122e (e.g., the second charge storage element SD2 may be distributed to the first through fourth plane regions of the unit pixel 122c and electrically connected to each of the first infrared light detection region 124-1, the second infrared light detection region 124-2, the third infrared light detection region 124-3, and the fourth infrared light detection region 124-4.

In an exemplary embodiment, the unit pixel 122c may further include a micro-lens layer MLL that guides the incident infrared light, the first incident visible light, and the second incident visible light into the infrared light detection layer IDL, the first visible light detection layer VDL1, and the second visible light detection layer VDL2, respectively. Here, the micro-lens layer MLL may include a plurality of micro-lenses ML. For example, the micro-lens layer MLL may be disposed on the infrared light detection layer IDL. In an exemplary embodiment, when guiding the incident infrared light to the infrared light detection layer IDL is not required in the unit pixel 122c, the micro-lens layer MLL may be disposed under the infrared light detection layer IDL. As described above, since the unit pixel 122c has a stacked structure in which the infrared light detection layer IDL is stacked on the first and second visible light detection layers VDL1 and VDL2, the unit pixel 122c may generate an image signal in a visible light band and an image signal in an infrared light band without any crosstalk between the image signals. In addition, since the unit pixel 122c has a stacked structure in which the infrared light detection layer IDL is stacked on the first and second visible light detection layers VDL1 and VDL2, the existence of the infrared light detection layer IDL does not have any influence (e.g., reduction in area, etc) on the first and second visible light detection layers VDL1 and VDL2 in the unit pixel 122e. Thus, the image sensor 100 may output a visible light image having a high resolution and an infrared light image having a high resolution. Since human's eyes are more sensitive to green color compared to other colors (e.g., red color and blue color), as illustrated in FIG. 6, the green color light detection regions (e.g., corresponding to the first through fourth non-color filter visible light detection regions 130-1, 130-2, 130-3, and 130-4) are twice the area of the blue color light detection regions 132-1 and 132-4 and the area of the red color light detection regions 132-2 and 132-3. However, the unit pixel 122c of the present inventive concept is not limited to such specific structure. In addition, although it is illustrated in FIG. 6 that the first and second charge storage elements SD1 and SD2 are arranged (e.g., distributed) to each of the first through fourth plane regions of the unit pixel 122c, at least one plane region of the first through fourth plane regions of the unit pixel 122c may be assigned to the first charge storage element SD1 and/or the second charge storage element SD2 as a dedicated region for the first charge storage element SD1 and/or the second charge storage element SD2.

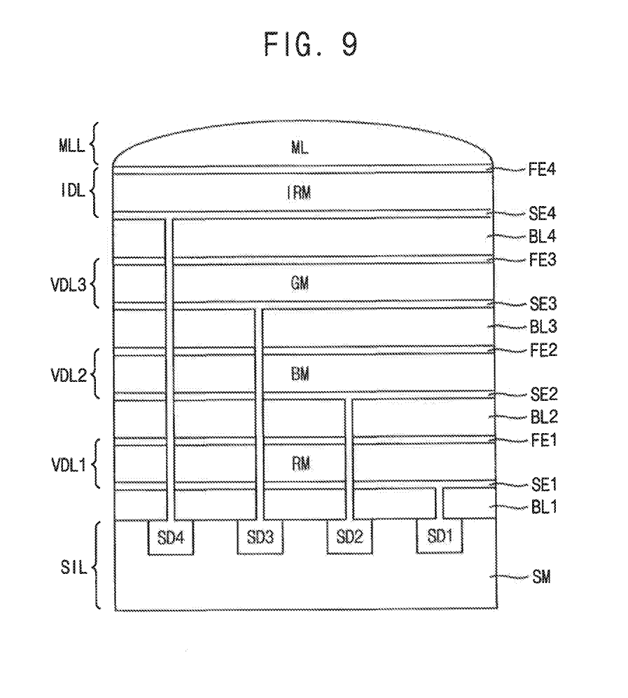

FIG. 8 is a diagram illustrating a unit pixel included in the image sensor of FIG. 1 according to an exemplary embodiment of the present inventive concept FIG. 9 is a cross-sectional view taken along D′-D″ line in FIG. 8.

Referring to FIGS. 8 and 9, a unit pixel 122d included in the image sensor 100 is illustrated. The unit pixel 122d may include a first visible light detection layer VDL1, a second visible light detection layer VDL2 that is stacked on the first visible light detection layer VDL1, a third visible light detection layer VDL3 that is stacked on the second visible light detection layer VDL2, and an infrared light detection layer IDL that is stacked on the third visible light detection layer VDL3.

The first visible light detection layer VDL1 may be stacked on a silicon layer SIL. A first insulation layer BL1 may be disposed between the silicon layer SIL and the first visible light detection layer VDL1. For example, the first insulation layer BL1 may include oxide, or may include oxide and nitride. The first visible light detection layer VDL1 may include a first visible light detection material RM (e.g., a red light detection material) between an upper electrode FE1 and a lower electrode SE1. The first visible light detection layer VDL1 may convert first incident visible light into first charges based on the first visible light detection material RM. For example, the first visible light detection material RM may include at least one of an organic material, a quantum dot, a III-V compound, or the like. For example, the organic material may include monomer material or low weight molecule material. In an exemplary embodiment, an amount of visible light absorption of the first visible light detection layer VDL1 may be adjusted based on a bias that is generated by a first voltage applied to the upper electrode FE1 and a second voltage applied to the lower electrode SE1. The second visible light detection layer VDL2 may be stacked on the first visible light detection layer VDL1. A second insulation layer BL2 may be disposed between the first visible light detection layer VDL1 and the second visible light detection layer VDL2. For example, the second insulation layer BL2 may include oxide, or may include oxide and nitride. The second visible light detection layer VDL2 may include a second visible light detection material BM (e.g., a blue light detection material) between an upper electrode FE2 and a lower electrode SE2. The second visible light detection layer VDL2 may convert second incident visible light into second charges based on the second visible light detection material BM. For example, the second visible light detection material BM may include at least one of an organic material, a quantum dot, a III-V compound, or the like. For example, the organic material may include monomer material or low weight molecule material. In an exemplary embodiment, an amount of visible light absorption of the second visible light detection layer VDL2 may be adjusted based on a bias that is generated by a first voltage applied to the upper electrode FE2 and a second voltage applied to the lower electrode SE2. The third visible light detection layer VDL3 may be stacked on the second visible light detection layer VDL2. A third insulation layer BL3 may be disposed between en the second visible light detection layer VDL2 and the third visible light detection layer VDL3. For example, the third insulation layer BL3 may include oxide, or may include oxide and nitride. The third visible light detection layer VDL3 may include a third visible light detection material GM (e.g., a green light detection material) between an upper electrode FE3 and a lower electrode SE3. The third visible light detection layer VDL3 may convert third incident visible light into third charges based on the third visible light detection material GM. For example, the third visible light detection material GM may include at least one of an organic material, a quantum dot, a III-V compound, or the like. For example, the organic material may include monomer material or low weight molecule material. In an exemplary embodiment, an amount of visible light absorption of the third visible light detection layer VDL3 may be adjusted based on a bias that is generated by a first voltage applied to the upper electrode FE3 and a second voltage applied to the lower electrode SE3. For example, the unit pixel 122d may detect the first through third incident visible lights based on a visible light detection material (e.g., a red light detection material, blue light detection material, or green light detection material) including at least one of an organic material, a quantum dot, a III-V compound, or the like. For example, the organic material may include monomer material or low weight molecule material.

The infrared light detection layer IDL may be stacked on the third visible light detection layer VDL3. A fourth insulation layer BL4 may be disposed between the infrared light detection layer IDL and the third visible light detection layer VDL3. For example, the fourth insulation layer BL4 may include oxide, or may include oxide and nitride. The infrared light detection layer IDL may include an infrared light detection material IRM between an upper electrode FE4 and a lower electrode SE4. The infrared light detection layer IDL may convert incident infrared light into fourth charges based on the infrared light detection material IRM. For example, the infrared light detection material IRM may include at least one of an organic material, a quantum dot, a III-V compound, or the like. For example, the organic material may include monomer material or low weight molecule material. In an exemplary embodiment, an amount of infrared light absorption of the infrared light detection layer IDL may be adjusted based on a bias that is generated by a first voltage applied to the upper electrode FE4 and a second voltage applied to the lower electrode SE4. The silicon layer SIL may include a first charge storage element SD1 that is electrically connected to the first visible light detection layer VDL1, a second charge storage element SD2 that is electrically connected to the second visible light detection layer VDL2 via the first visible light detection layer VDL1, a third charge storage element SD3 that is electrically connected to the third visible light detection layer VDL3 via the first and second visible light detection layers VDL1 and VDL2, and a fourth charge storage element SD4 that is electrically connected to the infrared light detection layer IDL via the first through third visible light detection layers VDL1, VDL2, and VDL3. For example, each of the first through fourth charge storage elements SD1, SD2, SD3, and SD4 may be an (n+)-type doping region formed in a (p)-type silicon region SM.

In an exemplary embodiment, the unit pixel 122d may further include a micro-lens layer MLL that guides the incident infrared light, the first incident visible light, the second incident visible light, and the third incident visible light into the infrared light detection layer IDL, the first visible light detection layer VDL1, the second visible light detection layer VDL2, and the third visible light detection layer VDL3, respectively. Here, the micro-lens layer MLL may include a plurality of micro-lenses ML. For example, the micro-lens layer IVILL may be disposed on the infrared light detection layer IDL. In an exemplary embodiment, when guiding the incident infrared light to the infrared light detection layer MI, is not required in the unit pixel 122d, the micro-lens layer MLL may be disposed under the infrared light detection layer IDL. As described above, since the unit pixel 122d has a stacked structure in which the infrared light detection layer IDL is stacked on the first through third visible light detection layers VDL1, VDL2, and VDL3, the unit pixel 122d may generate an image signal in a visible light band and an image signal in an infrared light band without any crosstalk between the image signals. In addition, since the unit pixel 122d has a stacked structure in which the infrared light detection layer IDL is stacked on the first through third visible light detection layers VDL1, VDL2, and VDL3, the existence of the infrared light detection layer IDL does not have any influence (e.g., reduction in area, etc) on the first through third visible light detection layers VDL1, VDL2, and VDL3 in the unit pixel 122d. Thus, the image sensor 100 may output a visible light image having a high resolution and an infrared light image having a high resolution. Although it is illustrated in FIG. 9 that the first through third visible light detection layers VDL1, VDL2, and VDL3 detect the first through third visible lights based on the first through third visible light detection materials, respectively, a structure of the unit pixel 122d of the present inventive concept is not limited thereto. For example, at least one of the first through third visible light detection layers VDL1, VDL2, and VDL3 may detect an incident visible light input through a color filter layer based on a photoelectric conversion element formed in the silicon layer SIL.

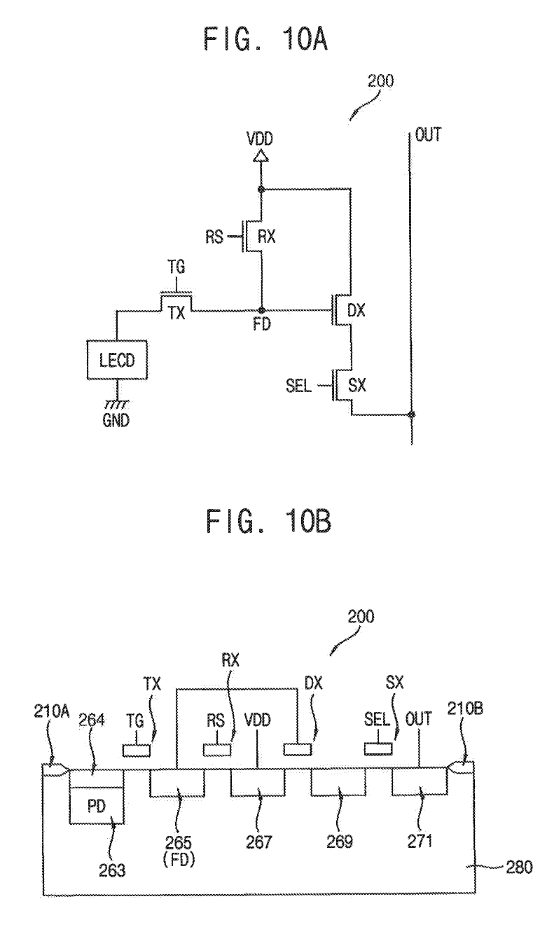

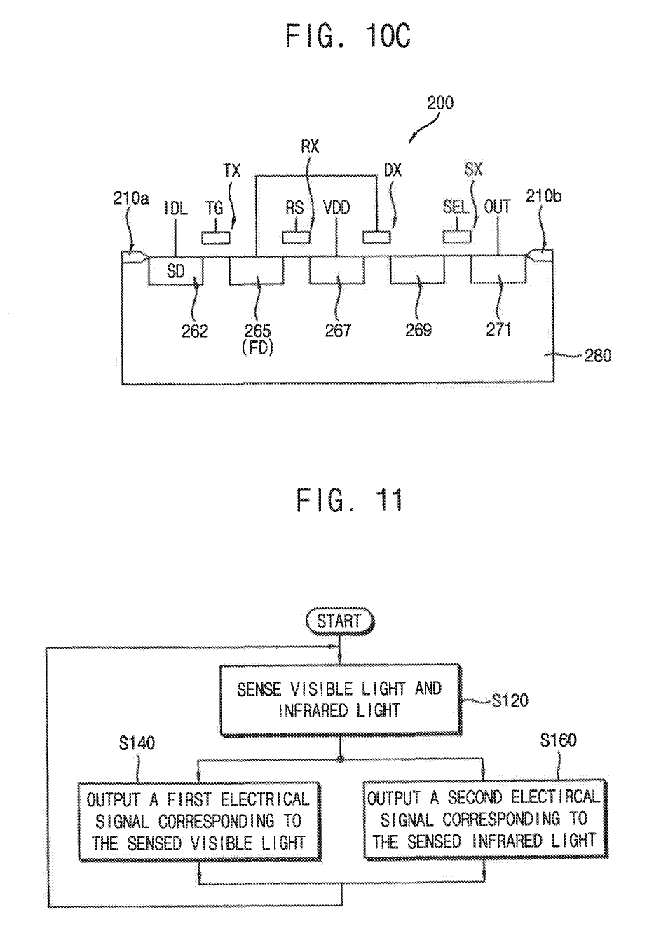

FIG. 10A is a circuit diagram of a sub-pixel of a unit pixel according to an exemplary embodiment of the present inventive concept.

Referring to FIG. 10A, a sub-pixel 200 (e.g., an infrared light detection pixel or a visible light detection pixel) included in the unit pixel 122 may include a photoelectric conversion unit LECD and a plurality of transistors TX, RX, DX, and SX. The sub-pixel 200 may have a one-transistor structure, a three-transistor structure, a four-transistor structure, or a five-transistor structure according to the number of transistors. For convenience of descriptions, it is assumed that the sub-pixel 200 has the four-transistor structure. However, a structure of the sub-pixel 200 of the present inventive concept is not limited to a structure of FIG. 10A.

The transistors TX, RX, DX, and SX may correspond to a transfer transistor TX, a reset transistor RX, a sensing transistor DX, and a select transistor SX, respectively. In addition, a floating diffusion node PD may be formed by a capacitor (not illustrated) at a coupling node of the transfer transistor TX, the reset transistor RX, and the sensing transistor DX. For example, a gate terminal of the transfer transistor TX may receive a transfer signal TG, a first terminal of the transfer transistor TX may be coupled to the photoelectric conversion unit LECD, and a second terminal of the transfer transistor TX may be coupled to the floating diffusion node VD. In addition, a gate terminal of the reset transistor RX may receive a reset signal RS, a first terminal of the reset transistor RX may be coupled to the floating diffusion node FD, and a second terminal of the reset transistor RX may be coupled to a high power voltage VDD. Further, a gate terminal of the sensing transistor DX may be coupled to the floating diffusion node FD, a first terminal of the sensing transistor DX may be coupled to a second terminal of the select transistor SX, and a second terminal of the sensing transistor DX may be coupled to the high power voltage VDD. In addition, a gate terminal of the select transistor SX may receive a row selection signal SEL, a first terminal of the select transistor SX may be coupled to an output terminal OUT, and the second terminal of the select transistor SX may be coupled to the first terminal of the sensing transistor DX. The photoelectric conversion unit LECD may correspond to a photoelectric conversion element (e.g., photodiode) when the sub-pixel 200 is the visible light detection pixel. The photoelectric conversion unit LECD may correspond to a combination of an infrared light detection layer and a charge storage element that is electrically connected to the infrared light detection layer when the sub-pixel 200 is the infrared light detection pixel. The photoelectric conversion unit LECD may be placed between the transfer transistor TX and a low power voltage (e.g., ground voltage) GND.

As for operations of the sub-pixel 200, the photoelectric conversion unit LECD may convert visible light or infrared light into charges and may accumulate the charges to generate accumulated charges. The transfer transistor TX may be turned-on based on the transfer signal. TG input to the gate terminal of the transfer transistor TX. Thus, the accumulated charges may be transferred to the floating diffusion node FD when the transfer transistor TX is turned-on. Here, the reset transistor RX may be maintained in a turn-off state and thus, an electric potential of the floating diffusion node FD may be changed by the accumulated charges transferred to the floating diffusion node FD. As the electric potential of the floating diffusion node FD is changed, an electric potential of the gate terminal of the sensing transistor DX may be changed. Thus, a bias of the first terminal of the sensing transistor DX (e.g., a bias of the second terminal of the select transistor SX) may be changed by the change in electric potential of the gate terminal of the sensing transistor DX. Here, when the row selection signal SEL is input to the gate terminal of the select transistor SX, an electrical signal corresponding to the accumulated charges may be output through the output ter al OUT. After the electrical signal corresponding to the accumulated charges is output through the output terminal OUT, the reset signal RS may be input to the gate terminal of the reset transistor RX to turn on the reset transistor RX, and the floating diffusion node FD may be initialized (e.g., a sensing process may be initialized). Since the afore-mentioned operation of the sub-pixel 200 is an example illustration, an operation of the sub-pixel 200 of the present inventive concept is not limited thereto.

In an exemplary embodiment, an operation of the sub-pixel 200 may be changed according to whether the sub-pixel 200 is the infrared light detection pixel or the visible light detection pixel. For example, an operation of the infrared light detection pixel may be different from an operation of the visible light detection pixel. For example, an operation of the transfer transistor TX may be omitted in the above operation of the sub-pixel 200. For example, the sub-pixel 200 may perform a so-called four-transistor operation that includes the operation of the transfer transistor TX, or in an exemplary embodiment, the sub pixel 200 may perform a so-called three-transistor operation that does not include the operation of the transfer transistor TX. For example, when the sub-pixel 200 performs the three-transistor operation, the transfer transistor TX may be continuously turned-on during the operation of the sub-pixel 200. In an exemplary embodiment, the sub-pixel 200 may perform the four-transistor operation when the sub-pixel 200 is the infrared light detection pixel, and may perform the four-transistor operation when the sub-pixel 200 is the visible light detection pixel. In an exemplary embodiment, the sub-pixel 200 may perform the three-transistor operation when the sub-pixel 200 is the infrared light detection pixel, and may perform the four-transistor operation when the sub-pixel 200 is the visible light detection pixel. In an exemplary embodiment, the sub-pixel 200 may perform the four-transistor operation when the sub-pixel 200 is the infrared light detection pixel, and may perform the three-transistor operation when the sub-pixel 200 is the visible light detection pixel. In an exemplary embodiment, the sub-pixel 200 may perform the three-transistor operation when the sub-pixel 200 is the infrared light detection pixel, and may perform the three-transistor operation when the sub-pixel 200 is the visible light detection pixel.

FIG. 10B is a diagram illustrating the sub-pixel of FIG. 10A when the sub-pixel of FIG. 10A is a visible light detection pixel according to an exemplary embodiment of the present inventive concept. FIG. 10C is a diagram illustrating the sub-pixel of FIG. 10A when the sub-pixel of FIG. 10A is an infrared light detection pixel according to an exemplary embodiment of the present inventive concept.

Referring to FIGS. 10B and 10C, an active region of the sub-pixel 200 may be defined by device isolation layers 210A and 210B on a semiconductor substrate 280 corresponding to a (p)-type silicon region. In an exemplary embodiment, as illustrated in FIG. 10B, when the sub-pixel 200 is the visible light detection pixel, a photoelectric conversion element PD (e.g., photodiode) may be formed in the semiconductor substrate 280. Here, the photoelectric conversion element PD may include an (n)-type doping region 263 and a (p)-type doping region 264. In addition, a first (n+)-type doping region 265 may be formed at a location that stands apart from the photoelectric conversion element PD by a specific distance. The first (n+)-type doping region 265 may act as the floating diffusion node FD. The gate terminal of the transfer transistor TX may be formed on the semiconductor substrate 280 at a location between the photoelectric conversion element PD and the first (n+)-type doping region 265. In an exemplary embodiment, as illustrated in FIG. 10C, when the sub-pixel 200 is the infrared light detection pixel, a charge storage element SD may be formed in the semiconductor substrate 280. Here, the charge storage element SD may include an (n+)-type doping region. The charge storage element SD may be electrically connected to the infrared light detection layer IDL of the unit pixel 122. In addition, a first n+)-type doping region 265 may be formed at a location that stands apart from the charge storage element SD by a specific distance. The first (n+)-type doping region 265 may act as the floating diffusion node FD. The gate terminal of the transfer transistor TX may be formed on the semiconductor substrate 280 at a location between the charge storage element SD and the first (n+)-type doping region 265. According to an exemplary embodiment, the unit pixel 200 may include a single charge storage element SD configured to store the charges detected by the infrared light detection layer IDL. As illustrated in FIGS. 10B and 10C, the gate terminal of the reset transistor RX may be formed on the semiconductor substrate 280 at a location between the first (n±)-type doping region 265 and the second (n+)-type doping region 267. Further, the gate terminal of the sensing transistor DX may be formed on the semiconductor substrate 280 at a location between the second (n+)-type doping region 267 and the third (n+)-type doping region 269. The gate terminal of the select transistor SX may be formed on the semiconductor substrate 280 at a location between the third (n+)-type doping region 269 and the fourth (n+)-type doping region 271. As illustrated in FIGS. 10A through 10C, the transfer signal TG may be input to the gate terminal of the transfer transistor TX. The reset signal RS may be input to the gate terminal of the reset transistor RX. The gate terminal of the sensing transistor DX may be coupled to the first (n+)-type doping region 265 (e.g., the floating diffusion node FD). The row selection signal SEL may be input to the gate terminal of the select transistor SX.

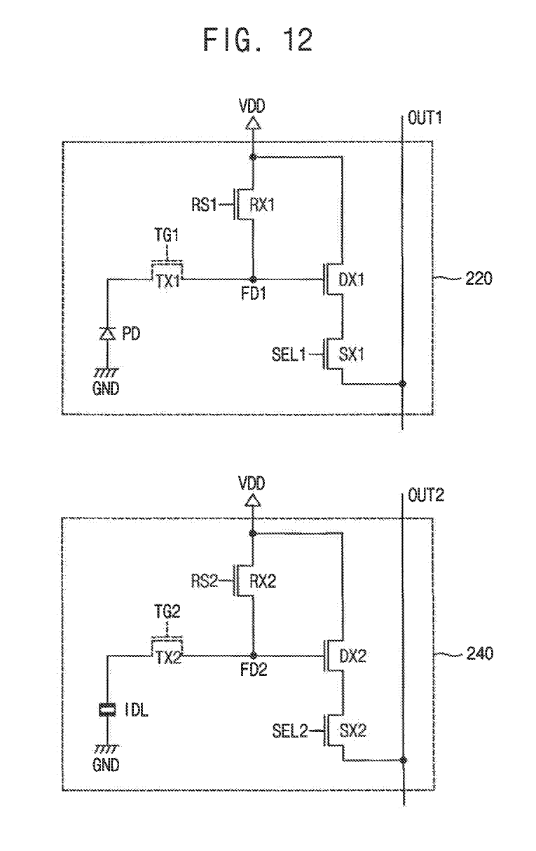

FIG. 11 is a flowchart illustrating an exemplary embodiment of the present inventive concept in which a first electrical signal and a second electrical signal are generated by a unit pixel included in the image sensor of FIG. 1. FIG. 12 are circuit diagrams of signal generation circuits in respective sub-pixels of a unit pixel included in the image sensor of FIG. 1.

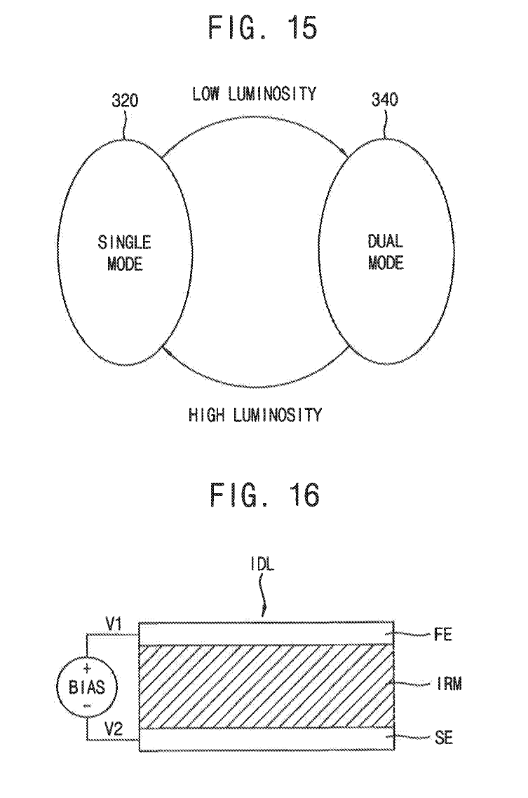

Referring to FIGS. 11 and 12, each of the sub-pixels 200 (e.g., a visible light detection pixel 220 and an infrared light detection pixel 240 of FIG. 12) of the unit pixel 122 may include a signal generation circuit. For example, when the unit pixel 122 is exposed to visible light and infrared light, the visible light detection pixel 220 and the infrared light detection pixel 240 may sense the visible light and the infrared light, respectively (S120). In addition, the visible light detection pixel 220 may output a first electrical signal corresponding to the sensed visible light (S140), and the infrared light detection pixel 240 may output a second electrical signal corresponding to the sensed infrared light (S160). Since the visible light detection pixel 220 includes a signal generation circuit and the infrared light detection pixel 240 includes a signal generation circuit, the unit pixel 122 may operate either in single mode wherein only one signal generation circuit, e.g., visible light detection pixel 220 is activated, or in dual mode wherein the visible light detection pixel 220 and the infrared light detection pixel 240 may concurrently generate the first electrical signal corresponding to an accumulated amount of first charges that are converted from the visible light and the second electrical signal corresponding to an accumulated amount of second charges that are converted from the infrared light, respectively. The single or dual mode operation will be further described with reference to FIG. 15. As described above, an operation of the sub-pixel 200 may be changed according to whether the sub-pixel 200 is the visible light detection pixel 220 or the infrared light detection pixel 240. For example, referring to FIG. 12, operations of the transfer transistors TX1 and TX2 may be omitted in the operation of the sub-pixel 200. In an exemplary embodiment, the visible light detection pixel 220 and the infrared light detection pixel 240 may operate using a four-transistor embodiment. In an exemplary embodiment, the visible light detection pixel 220 may use a three-transistor embodiment while the infrared light detection pixel 240 uses a four-transistor embodiment. In another exemplary embodiment, the visible light detection pixel 220 may use a four-transistor embodiment while the infrared light detection pixel 240 uses a three-transistor embodiment, and so on.

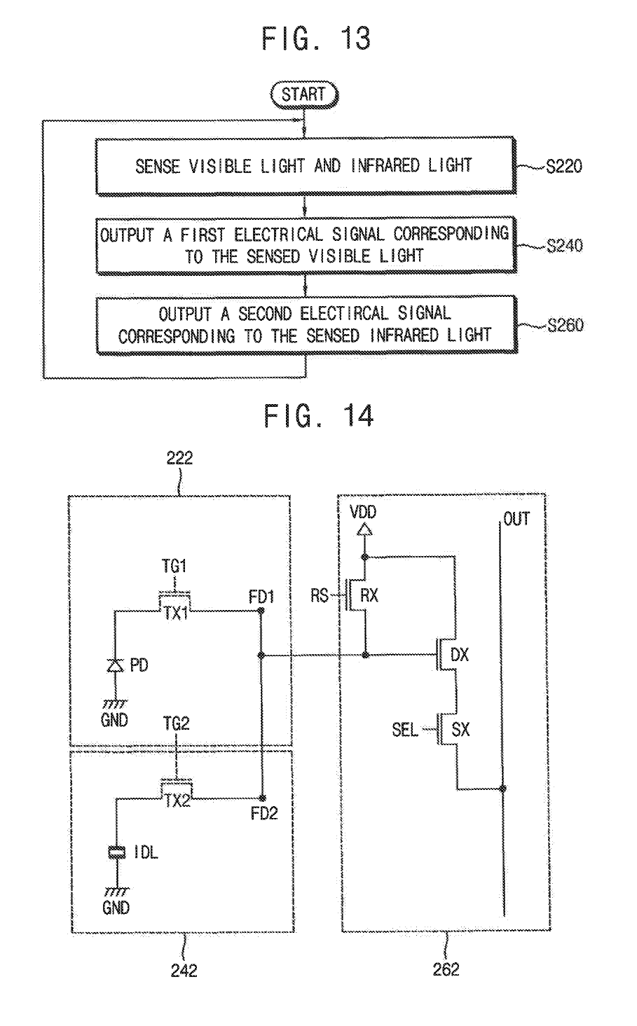

FIG. 13 is a flowchart illustrating an exemplary embodiment of the present inventive concept in which a first electrical signal and a second electrical signal are generated by a unit pixel included in the image sensor of FIG. 1. FIG. 14 is a circuit diagram of a signal generation circuit that is shared by respective sub-pixels of a unit pixel according to an exemplary embodiment of the present inventive concept.

Referring to FIGS. 13 and 14, the sub-pixels 200 (e.g., the visible light detection pixel 222 and 262 and the infrared light detection pixel 242 and 262 of FIG. 14) of the unit pixel 122 may share a signal generation circuit 262. For example, when the unit pixel 122 is exposed to visible light and infrared light, the visible light detection pixel 222 and 262 and the infrared light detection pixel 242 and 262 may sense the visible light and the infrared light, respectively (S220). In addition, the visible light detection pixel 222 and 262 may output a first electrical signal corresponding to the sensed visible light (S240). In addition, the infrared light detection pixel 242 and 262 may output a second electrical signal corresponding to the sensed infrared light (S260). Here, since the visible light detection pixel 222 and 262 and the infrared light detection pixel 242 and 262 shares the signal generation circuit 262, the visible light detection pixel 222 and 262 and the infrared light detection pixel 242 and 262 may sequentially generate the first electrical signal corresponding to an accumulated amount of first charges that are converted from the visible light and the second electrical signal corresponding to an accumulated amount of second charges that are converted from the infrared light. Although it is described above that the infrared light detection pixel 242 and 262 outputs the second electrical signal corresponding to the sensed infrared light (S260) after the visible light detection pixel 222 and 262 outputs the first electrical signal corresponding to the visible light (S240), the visible light detection pixel 222 and 262 may output the first electrical signal corresponding to the visible light (S240) after the infrared light detection pixel 242 and 262 outputs the second electrical signal corresponding to the sensed infrared light (S260). As described above, an operation of the sub-pixel 200 may be changed according to whether the sub-pixel 200 is the visible light detection pixel 222 and 262 or the infrared light detection pixel 242 and 262. For example, operations of the transfer transistor TX1 and TX2 may be omitted in the operation of the sub-pixel 200. In an exemplary embodiment, the visible light detection pixel 222 and 262 may perform the four-transistor operation, and the infrared light detection pixel 242 and 262 may perform the four-transistor operation. In an exemplary embodiment, the visible light detection pixel 222 and 262 may perform the three-transistor operation, and the infrared light detection pixel 242 and 262 may perform the four-transistor operation. In an exemplary embodiment, the visible light detection pixel 222 and 262 may perform the four-transistor operation, and the infrared light detection pixel 242 and 262 may perform the three-transistor operation. In an exemplary embodiment, the visible light detection pixel 222 and 262 may perform the three-transistor operation, and the infrared light detection pixel 242 and 262 may perform the three-transistor operation.

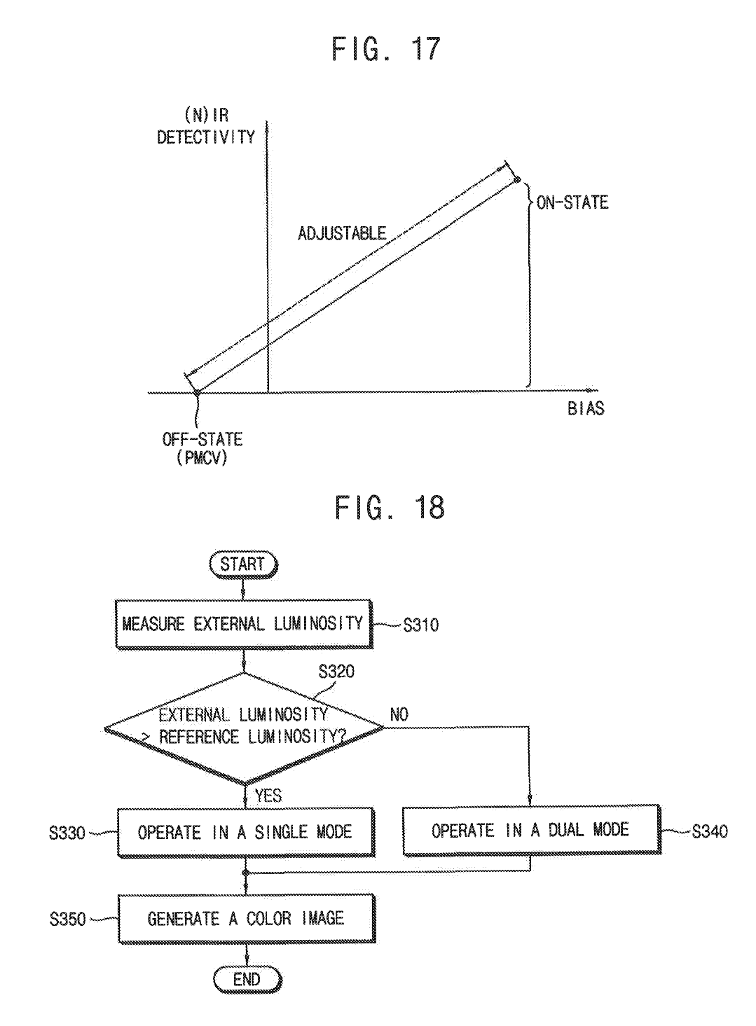

FIG. 15 is a diagram illustrating an operating mode of the image sensor of FIG. 1 according to an exemplary embodiment of the present inventive concept. FIG. 16 is a diagram illustrating an exemplary embodiment of the present inventive concept in which a bias is applied to an infrared light detection pixel of a unit pixel included in the image sensor of FIG. 1. FIG. 17 is a graph illustrating an exemplary embodiment of the present inventive concept in which an amount of infrared light absorption is adjusted based on a bias applied to an infrared light detection pixel of a unit pixel included in the image sensor of FIG. 1.

Referring to FIGS. 15 through 17, the image sensor 100 may operate in a single mode 320 or in a dual mode 340. For example, the image sensor 100 may generate a color image (e.g., a visible light image) only based on an image signal in a visible light band in the single mode 320 of the image sensor 100. In addition, the image sensor 100 may generate the color image based on both an image signal in a visible light band and an image signal in an infrared light band in the dual mode 340 of the image sensor 100. Thus, in the single mode 320 of the image sensor 100, a visible light detection pixel of the unit pixel 122 may be activated (e.g., visible light may be sensed) and an infrared light detection pixel of the unit pixel 122 may be deactivated (e.g., infrared light may not be sensed). In addition, in the dual mode 340 of the image sensor 100, the visible light detection pixel of the unit pixel 122 may be activated (e.g., the visible light may be sensed) and the infrared light detection pixel of the unit pixel 122 may be activated (e.g., the infrared light may be sensed).

The unit pixel 122 may include the visible light detection pixel and the infrared light detection pixel. The visible light detection pixel may convert an incident visible light input through a color filter layer into first charges based on a photoelectric conversion element formed in a silicon layer, and may generate a first electrical signal corresponding to an accumulated amount of the first charges. The infrared light detection pixel may convert an incident infrared light into second charges based on an infrared light detection layer IDL including an infrared light detection material IRM between an upper electrode FE and a lower electrode SE, and may generate a second electrical signal corresponding to an accumulated amount of the second charges. For example, the infrared light detection material IRM may include at least one of an organic material, a quantum dot, or the like. For example, the organic material may include monomer material or low weight molecule material. Here, as illustrated in FIG. 16, an amount of infrared light absorption of the infrared light detection layer IDL may be adjusted based on a bias BIAS that is generated by a first voltage V1 applied to the upper electrode FE and a second voltage V2 applied to the lower electrode SE. In addition, sensitivity of the infrared light detection pixel may be adjusted by adjusting an amount of infrared light absorption of the infrared light detection layer IDL. In addition, the visible light detection pixel may be arranged in a Bayer pattern shape in the unit pixel 122. In an exemplary embodiment, the visible light detection pixel and the infrared light detection pixel included in the unit pixel 122 may be arranged adjacently to each other from a top view. For example, the unit pixel 122 may have a non-stacked structure in which one visible light detection pixel (e.g., one G sub-pixel) is replaced with the infrared light detection pixel in a unit pixel according to the related art including only visible light detection pixels (e.g., R-G-G-B sub-pixel combination). In an exemplary embodiment, the infrared light detection pixel may be stacked on the visible light detection pixel in the unit pixel 122. For example, the unit pixel 122 may have a stacked structure in which the infrared light detection pixel is inserted on the visible light detection pixels in the unit pixel according to the related art (e.g., R-G-G-B sub-pixel combination). In this case, since the infrared light detection pixel absorbs more infrared light over the visible light detection pixels, the infrared light detection pixel may function as an IR cut filter for the visible light detection pixels in the unit pixel 122.

As illustrated in FIG. 17, when a bias BIAS that is generated by the first voltage V1 applied to the upper electrode FE and the second voltage V2 applied to the lower electrode SE is greater than a predetermined mode-change reference value PMCV, the infrared light detection pixel of the unit pixel 122 may be activated (e.g., indicated as ON-STATE). In addition, when a bias BIAS that is generated by the first voltage V1 applied to the upper electrode FE and the second voltage V2 applied to the lower electrode SE is less than the mode-change reference value PMCV, the infrared light detection pixel of the unit pixel 122 may be deactivated (e.g., indicated as OFF-STATE). Thus, when a bias BIAS that is generated by the first voltage V1 applied to the upper electrode FE and the second voltage V2 applied to the lower electrode SE is less than the mode-change reference value PMCV, the image sensor 100 may generate a color image only based on incident visible light sensed by the visible light detection pixel. In this instance, the image sensor 100 operates in the single mode 320. In addition, when a bias BIAS that is generated by the first voltage V1 applied to the upper electrode FE and the second voltage V2 applied to the lower electrode SE is greater than the mode-change reference value PMCV, the image sensor 100 may generate a color image based on both incident visible light sensed by the visible light detection pixel and an incident infrared light sensed by the infrared light detection pixel. In such case, the image sensor 100 operates in the dual mode 340. When a bias BIAS that is generated by the first voltage V1 applied to the upper electrode FE and the second voltage V2 applied to the lower electrode SE is greater than the mode-change reference value PMCV, an amount of infrared light absorption of the infrared light detection layer IDL may increase as the bias BIAS that is generated by the first voltage V1 applied to the upper electrode FE and the second voltage V2 applied to the lower electrode SE increases. In addition, when a bias BIAS that is generated by the first voltage V1 applied to the upper electrode FE and the second voltage V2 applied to the lower electrode SE is greater than the mode-change reference value PMCV, amount of infrared light absorption of the infrared light detection layer IDL may decrease as the bias BIAS that is generated by the first voltage V1 applied to the upper electrode FE and the second voltage V2 applied to the lower electrode SE decreases. Therefore, when the image sensor 100 operates in the dual mode 320, an amount of infrared light absorption of the infrared light detection layer IDL may be adjusted (e.g., indicated as ADJUSTABLE) according to requirements of the image sensor 100 (e.g., external luminosity, etc). For example, when the image sensor 100 operates in the dual mode 320, sensitivity of the infrared light detection pixel (e.g., sensitivity of the unit pixel 122) may be adjusted.

A unit pixel according to the related art may include an IR pass filter for the infrared light detection pixel. Since an infrared light transmissivity of the IR pass filter is fixed, the unit pixel including the IR pass filter may not adjust sensitivity of the infrared tight detection pixel and may not activate/deactivate the infrared light detection pixel. According to an exemplary embodiment of the present inventive concept, since the infrared light detection pixel of the unit pixel 122 includes the infrared light detection layer IDL that includes the infrared light detection material IRM (e.g., an organic material or a quantum dot) between the upper electrode FE and the lower electrode SE, the unit pixel 122 may adjust sensitivity of the infrared light detection pixel and may activate/deactivate the infrared light detection pixel by adjusting a bias BIAS that is generated by the first voltage V1 applied to the upper electrode FE and the second voltage V2 applied to the lower electrode SE. Therefore, when the image sensor 100 generates a color image (e.g., a visible light image), the image sensor 100 may use infrared light information (e.g., an image signal in an infrared light band) to generate a high-quality color image from which a color mixture, a noise, etc are eliminated (or reduced). For example, if external luminosity is relatively high (e.g., outdoor area or daytime), the image sensor 100 may generate a high-quality color image only based on an image signal in a visible light band by deactivating the infrared light detection pixel of the unit pixel 122. In addition, if external luminosity is relatively low (e.g., indoor area or nighttime), the image sensor 100 may generate a high-quality color image based on both an image signal in a visible light band and an image signal in an infrared light band by activating the infrared light detection pixel of the unit pixel 122. Here, the unit pixel 122 may adjust sensitivity of the infrared light detection pixel by adjusting an amount of infrared light absorption of the infrared light detection layer IDL included in the infrared light detection pixel (e.g., indicated as ADJUSTABLE). Although it is described above that the image sensor 100 operates in the single mode 320 or in the dual mode 340 to generate a color image, the image sensor 100 may basically operate in an individual mode to generate a visible light image and/or an infrared light image as described with reference to FIGS. 1 through 14. For example, when the image sensor 100 operates in the individual mode, the image sensor 100 may generate an infrared light image by activating the infrared light detection pixel of the unit pixel 122 (e.g., an infrared light imaging such as iris recognition, etc). In addition, the image sensor 100 may not generate an infrared light image by deactivating the infrared light detection pixel of the unit pixel 122 (e.g., a visible light imaging such as a color image capture, etc).

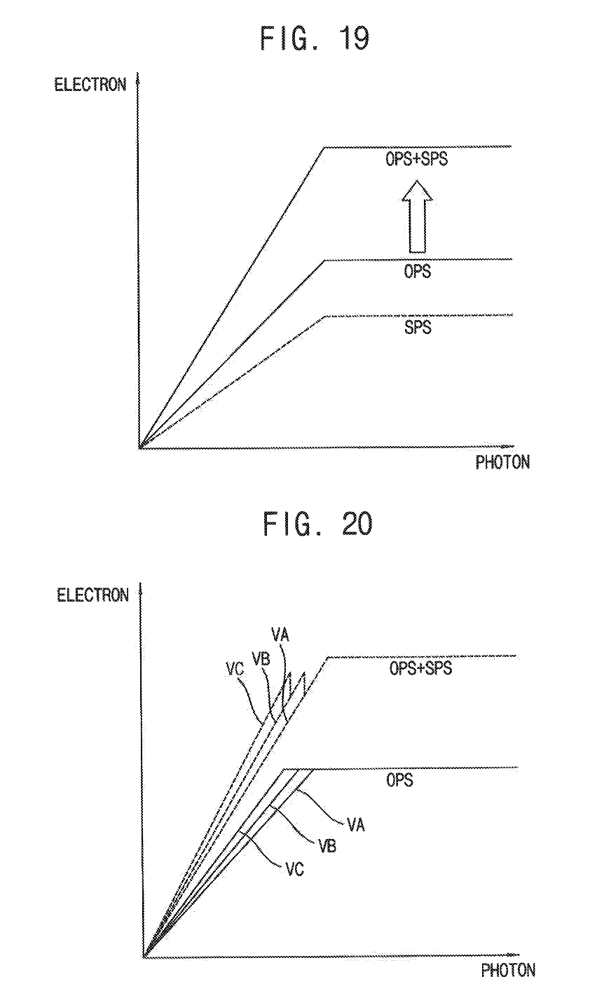

FIG. 18 is a flowchart illustrating an exemplary embodiment of the present inventive concept in which the image sensor of FIG. 1 determines an operating mode based on external luminosity. FIGS. 19 and 20 are graphs illustrating sensitivity of a unit pixel included in the image sensor of FIG. 1 is increased in a dual mode.

Referring to FIGS. 18 through 20, it is illustrated that the image sensor 100 determines an operating mode based on external luminosity. For example, the image sensor 100 may measure external luminosity (S310), and then may determine whether the external luminosity is greater than a predetermined reference luminosity (S320). Here, when the external luminosity is greater than the reference luminosity, the image sensor 100 may operate in a single mode (S330), for example, the image sensor 100 may deactivate the infrared light detection pixel of the unit pixel 122. Thus, the image sensor 100 may generate a color image only based on an image signal in a visible light band. When the external luminosity is less than the reference luminosity, the image sensor 100 may operate in a dual mode (S340), for example, the image sensor 100 may also activate the infrared light detection pixel of the unit pixel 122. Thus, the image sensor 100 may generate a color image based on both an image signal in a visible light band and an image signal in an infrared light band. Next, the image sensor 100 may generate a color image (e.g., visible light image) (S350) only based on an image signal in a visible light band or based on both an image signal in a visible light band and an image signal in an infrared light band. As described above, the image sensor 100 may generate a high-quality (e.g., clear) color image by deactivating the infrared light detection pixel of the unit pixel 122 when the external luminosity is greater than the reference luminosity. In addition, the image sensor 100 may generate a high-quality (e.g., clear) color image by activating the infrared light detection pixel of the unit pixel 122 when the external luminosity is less than the reference luminosity (e.g., stray light environment). For example, the image sensor 100 may implement an optimum imaging condition by adjusting a bias BIAS applied to the infrared light detection layer IDL included in the infrared light detection pixel of the unit pixel 122 based on the external luminosity.

A reason why sensitivity of the unit pixel 122 is increased in the dual mode is shown in FIGS. 19 and 20. As described above, the image sensor 100 may generate a high-quality color image by activating the infrared light detection pixel of the unit pixel 122 when the external luminosity is less than the reference luminosity. For example, since luminosity of visible light is insufficient when the external luminosity is less than the reference luminosity, an image signal SPS that is output from the visible light detection pixel (e.g., an image signal in a visible light band) may be relatively weak. Thus, the image sensor 100 generates a color image only based on the image signal SPS that is output from the visible light detection pixel and may not generate a high-quality color image due to color mixture, noise, etc. An image signal OPS that is output from the infrared light detection pixel (e.g., an image signal in an infrared light band) may have a specific level regardless of the luminosity of the visible light even when the luminosity of the visible light is insufficient (e.g., even when the external luminosity is less than the reference luminosity). Hence, when the image sensor 100 generates a color image based on a combination (e.g., a sum) of the image signal SPS that is output from the visible light detection pixel and the image signal OPS that is output from the infrared light detection pixel, the color mixture and noise, etc are eliminated or reduced. As described above, the image sensor 100 may increase sensitivity of the unit pixel 122 by activating the infrared light detection pixel when the external luminosity is less than the reference luminosity. In addition, when the infrared light detection pixel of the unit pixel 122 is activated in the image sensor 100, the image sensor 100 may finely adjust sensitivity of the unit pixel 122 by adjusting a bias BIAS applied to the infrared light detection layer IDL of the infrared light detection pixel. For example, as illustrated in FIG. 20, when the infrared light detection pixel of the unit pixel 122 is activated in the image sensor 100, sensitivity of the infrared light detection pixel may increase as the bias BIAS applied to the infrared light detection layer IDL of the infrared light detection pixel increases (e.g., in order of listing: VA, VB, and VC). In addition, sensitivity of the unit pixel 122 may also increase as sensitivity of the infrared light detection pixel increases.

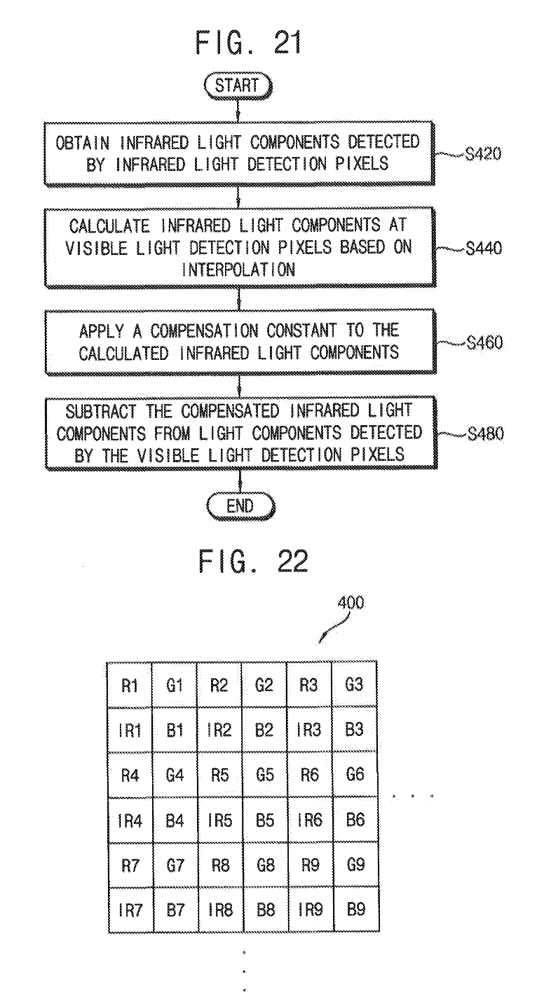

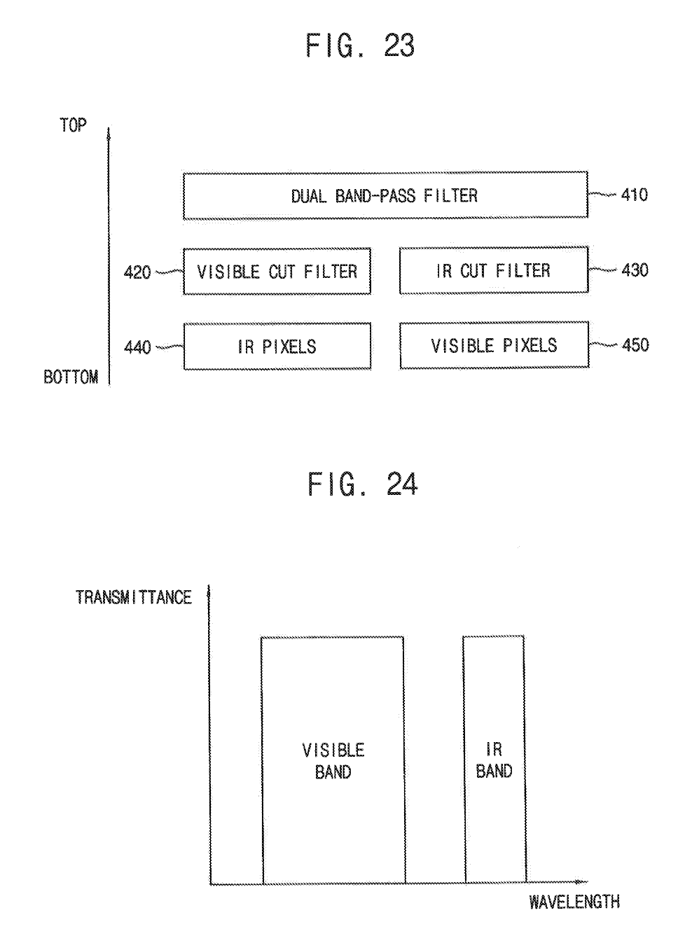

FIG. 21 is a flowchart illustrating a method of eliminating an infrared light noise for an image sensor according to an exemplary embodiment of the present inventive concept. FIG. 22 is a diagram illustrating a pixel array of an image sensor employing the method of FIG. 21 according to an exemplary embodiment of the present inventive concept. FIG. 23 is a diagram illustrating a filter structure of a unit pixel included in the pixel array of FIG. 22 according to an exemplary embodiment of the present inventive concept.

Referring to FIGS. 21 through 23, the method of FIG. 21 may be applied to a pixel array 400 (illustrated in FIG. 22) having a structure in which a dual band-pass filter 410 is disposed on infrared light detection pixels 440 and visible light detection pixels 450, a visible light cut filter 420 is disposed on the infrared light detection pixels 440, and an infrared light cut filter 430 is disposed on the visible light detection pixels 450 (illustrated in FIG. 23). For example, referring to FIG. 21, infrared light components may be detected by the infrared light detection pixels 440 (S420), for example, the infrared light detection pixels 440 may include a plurality of infrared light detection pixels IR1 through IRk, where k is an integer greater than or equal to 1. In addition, infrared light components at the visible light detection pixels 450 may be calculated based on interpolation between the infrared light components detected by the infrared light detection pixels 440 (S440). For example, the visible detection pixels 450 may include a plurality of visible light detection pixels Ri, Bi, and Gi, where i is an integer greater than or equal to 1. In addition, a compensation constant may be applied to the calculated infrared light components (S460), and the compensated infrared light components may be subtracted from light components detected by the visible light detection pixels 450 (S480). Thus, according to an exemplary embodiment of the present inventive concept illustrated in FIG. 21, an infrared light noise may be eliminated based on information (e.g., infrared light components or image signals in an infrared light band) output from the infrared light detection pixels 440. Here, the infrared light noise refers to as residual infrared light components included in the light components detected by the visible light detection pixels 450. The residual infrared light components may be generated when the infrared light cut filter 430 imperfectly cut the infrared light components to be incident to the visible light detection pixels 450.

Referring back to FIG. 21, the infrared light components may be detected by the infrared light detection pixels 440 (S420). As illustrated in FIG. 23, the dual band-pass filter 410 and the visible light cut filter 420 may be disposed on the infrared light detection pixels 440. For example, the dual band-pass filter 410 may be disposed on a portion of the visible light cut filter 420, and the visible light cut filter 420 may be disposed on the infrared light detection pixels 440. Although it is illustrated in FIG. 23 that the dual band-pass filter 410 is disposed on the visible light cut filter 420, the dual band-pass filter 410 may be disposed under the visible light cut filter 420 according to an exemplary embodiment of the present inventive concept. For example, after a visible light component and an infrared light component included in an incident light pass through the dual band-pass filter 410, the visible light component may be cut by the visible light cut filter 420. Accordingly, only the infrared light component reaches the infrared light detection pixels 440 and thus, the infrared light detection pixel 440 may accurately detect only the infrared light component. In addition, the infrared light components at the visible light detection pixels 450 may be calculated based on the interpolations between the infrared light components detected by the infrared light detection pixels 440 (S440). For example, when an interpolation is performed between a first infrared light component detected by a first infrared light detection pixel IR1 of the plurality of infrared light detection pixels IR1 through IRk and a second infrared light component detected by a second infrared light detection pixel IR2 of the plurality of infrared light detection pixels IR1 through IRk, an infrared light component at a visible light detection pixel B1 of the plurality of visible light detection pixels Ri, Bi, and Gi may be calculated, for example, the visible light detection pixel B1 may be positioned between the first infrared light detection pixel IR1 and the second infrared light detection pixel IR2. In an exemplary embodiment, an infrared light component at a specific visible light detection pixel 450 may be calculated based on interpolation between infrared light components detected by infrared light detection pixels 440 that are adjacent to the specific visible light detection pixel 450. In an exemplary embodiment, an infrared light component at a specific visible light detection pixel 450 may be calculated based on interpolation between infrared light components detected by infrared light detection pixels 440 that are located within a predetermined distance from the specific visible light detection pixel 450. However, interpolation performed by the method of FIG. 21 according to an exemplary embodiment of the present inventive concept is not limited thereto. In an exemplary embodiment, noise reduction (e.g., by a kernel method, etc) may be performed when the interpolation is performed.

In addition, the compensation constant may be applied to the calculated infrared light components (S460). As illustrated in FIG. 23, the dual band-pass filter 410 and the infrared light cut filter 430 may be disposed on the visible light detection pixels 450. For example, the dual band-pass filter 410 may be disposed on a portion of the infrared light cut filter 430, and the infrared light cut filter 430 may be disposed on the visible light detection pixels 450. Although it is illustrated in FIG. 23 that the dual band-pass filter 410 is disposed on the infrared light cut filter 430, the dual band-pass filter 410 may be disposed under the infrared light cut filter 430. For example, after the visible light component and the infrared light component included in the incident light pass through the dual band-pass filter 410, the infrared light component may be cut by the infrared light cut filter 430. Accordingly, only the visible light component reaches the visible light detection pixels 450 and thus, the visible light detection pixel 450 may accurately detect only the visible light component. For example, the visible light cut filter 420 may effectively cut the visible light component and the infrared light cut filter 430 may not effectively cut the infrared light component. Thus, the method of FIG. 21 may use the compensation constant for compensating the limit of the infrared light cut filter 430 that the infrared light cut filter 430 imperfectly cut the infrared light component. For example, the method of FIG. 21 may apply the compensation constant to the calculated infrared light components.

In addition, the compensated infrared light components (e.g., corresponding to the residual infrared light components included in the light components detected by the visible light detection pixels 450) from the light components detected by the visible light detection pixels 450 (S480). As described above, since the light components detected by the visible light detection pixels 450 include the visible light components and the residual infrared light components generated due to the limit of the infrared light cut filter 430, the residual infrared light components may be eliminated by subtracting the compensated infrared light components from the light components detected by the visible light detection pixels 450. In an exemplary embodiment, the method of FIG. 21 may be expressed by [Equation 1] below.

R=(R with IRrc)−[f(IRref)*coeff_{—}r]

G=(G with IRgc)−[f(IRref)*coeff_{—}g]

B=(B with IRbc)−[f(IRref)*coeff_{—}b] [Equation 1]

In [Equation 1], R denotes a red color light component without an infrared light component, G denotes a green color light component without an infrared light component, and B denotes a blue color light component without an infrared light component. In addition, (R with IRrc) denotes a light component detected by a red color light detection pixel (e.g., a red color light component R with an infrared light component IRrc), (G with IRgc) denotes a light component detected by a green color light detection pixel (e.g., a green color light component G with an infrared light component IRgc), and (B with IRbc) denotes a light component detected by a blue color light detection pixel (e.g., a blue color light component B with an infrared light component IRbc). Further, IRref denotes an infrared light component detected by an infrared light detection pixel. In addition, f denotes a function for performing interpolation between infrared light components detected by infrared light detection pixels. Further, coeff_r denotes a compensation constant for a red color light detection pixel, coeff_g denotes a compensation constant for a green color light detection pixel, d coeff_b denotes a compensation constant for a blue color light detection pixel.

As described above, when the image sensor 100 generates a visible light image and an infrared light image, an infrared light (IR) contamination due to the infrared light noise may occur in the visible light image because the infrared light cut filter 430 that is disposed on the visible light detection pixels 450 has low performance. Thus, the infrared light noise in the visible light image may be eliminated based on the information (e.g., infrared light components or image signals in an infrared light band) output from the infrared light detection pixels 440. Thus, the method of FIG. 21 according to an exemplary embodiment of the present inventive concept may efficiently prevent a color mixture, a noise, etc due to crosstalk of the infrared light components.

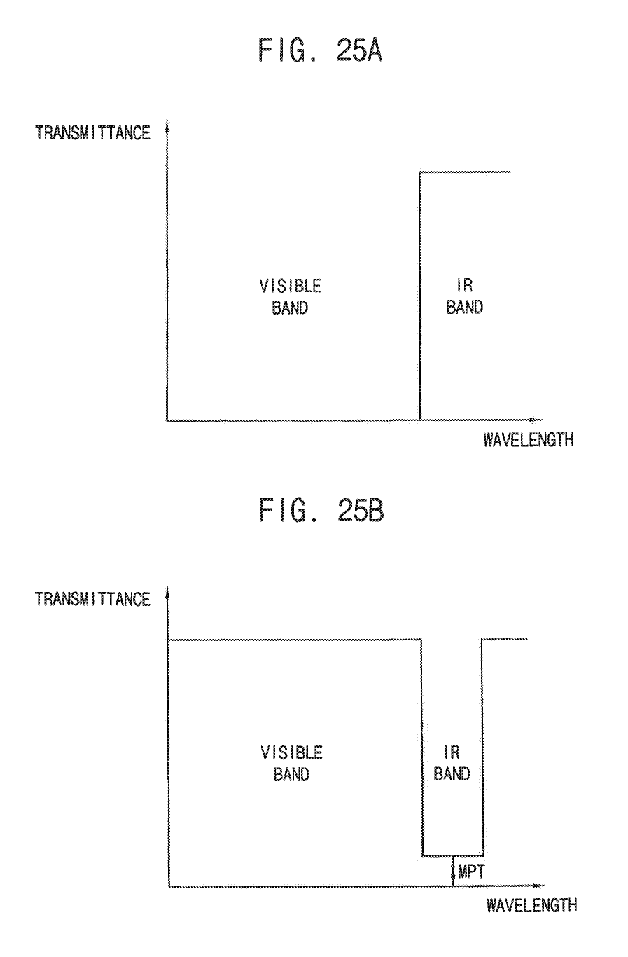

FIG. 24 is a graph illustrating an operation of a dual band-pass filter in the filter structure of FIG. 23 according to an exemplary embodiment of the present inventive concept. FIG. 25A is a graph illustrating an operation of a visible light cut filter in the filter structure of FIG. 23 according to an exemplary embodiment of the present inventive concept. FIG. 25B is a graph illustrating an operation of an infrared light cut filter in the filter structure of FIG. 23 according to an exemplary embodiment of the present inventive concept.

Referring to FIGS. 24 through 25B, respective operations of the dual band-pass filter 410, the visible light cut filter 420, and the infrared light cut filter 430 included in the pixel array 400 are illustrated, where the method of FIG. 21 is applied to the pixel array 400. As described above, the dual band-pass filter 410 and the visible light cut filter 420 may be disposed on the infrared light detection pixels 440. Thus, as illustrated in FIGS. 24 and 25A, after a visible light component and an infrared light component included in an incident light pass through the dual band-pass filter 410, the visible light component may be cut by the visible light cut filter 420. Accordingly, only the infrared light component may reach the infrared light detection pixels 440. In addition, the dual band-pass filter 410 and the infrared light cut filter 430 may be disposed on the visible light detection pixels 450. Thus, as illustrated in FIGS. 24 and 25B, after the visible light component and the infrared light component included in the incident light pass through the dual band-pass filter 410, the infrared light component may be cut by the infrared light cut filter 430. Accordingly, only the visible light component may reach the visible light detection pixels 450. For example, as illustrated in FIGS. 25A and 25B, the visible light cut filter 420 may perfectly cut the visible light component and the infrared light cut filter 430 may not perfectly cut the infrared light component. Thus, the method of FIG. 21 may use the compensation constant for compensating the limit of the infrared light cut filter 430 that the infrared light cut filter 430 imperfectly cut the infrared light component (e.g., indicated as MPT).

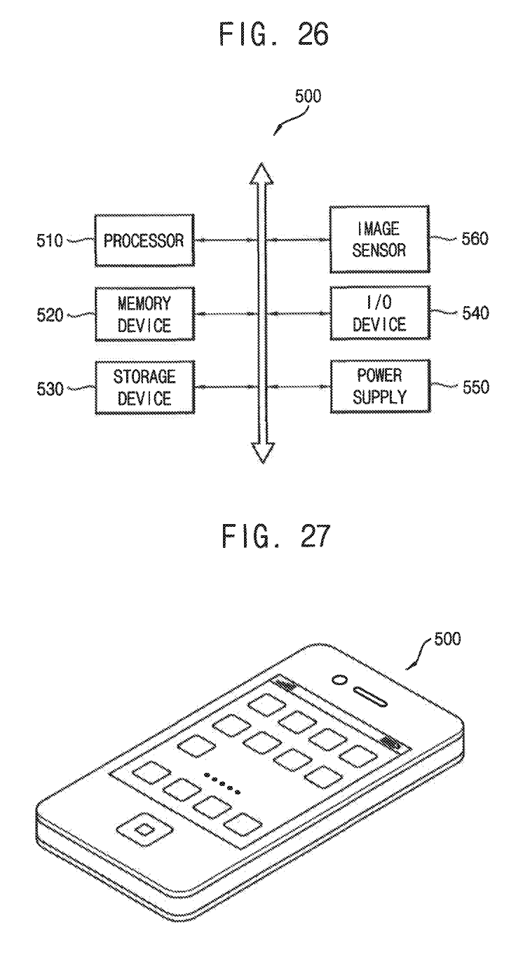

FIG. 26 is a block diagram illustrating an electronic device according to an exemplary embodiment of the present inventive concept. FIG. 27 is a diagram illustrating an exemplary embodiment of the present inventive concept in which the electronic device of FIG. 26 is implemented as a smart phone.

Referring to FIGS. 26 and 27, an electronic device 500 may include a processor 510, a memory device 520, a storage device 530, an input/output (I/O) device 540, a power supply 550, and an image sensor 560. Here, the image sensor 560 may correspond to the image sensor 100 of FIG. 1. In addition, the electronic device 500 may further include a plurality of ports for communicating with a video card, a sound card, a memory card, a universal serial bus (USB) device, other electronic devices, etc. For example, as illustrated in FIG. 27, the electronic device 500 may be implemented as a smart phone.

The processor 510 may perform various computing functions. The processor 510 may be a micro processor, a central processing unit (CPU), an application processor (AP), etc. The processor 510 may be coupled to other components via an address bus, a control bus, a data bus, etc. In an exemplary embodiment, the processor 510 may be coupled to an extended bus such as a peripheral component interconnection (PCI) bus. The memory device 520 may store data for operations of the electronic device 500. For example, the memory device 520 may include a volatile semiconductor memory device such as a dynamic random access memory (DRAM) device, a static random access memory (SRAM) device, a mobile DRAM, etc, and/or a non-volatile semiconductor memory device such as an erasable programmable read-only memory (EPROM) device, an electrically erasable programmable able read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc. The storage device 530 may be a solid state drive (SSD) device, a hard disk drive (FWD) device, a CD-ROM device, etc.

The I/O device 540 may include an input device such as a keyboard, a keypad, a touchpad, a touch-screen, a mouse, etc, and an output device such as a display device, a speaker, a printer, etc. The power supply 550 may provide power for operations of the electronic device 500. The image sensor 560 may communicate with other components via the buses or other communication links. As described above, the image sensor 560 may include a pixel array, an ADC unit, a DSP unit, and a controller. The pixel array may include a plurality of unit pixels each having a stacked structure in which an infrared light detection pixel and a visible light detection pixel are stacked. For example, each unit pixel may have a structure in which an infrared light detection layer is stacked on a visible light detection layer. The ADC unit may convert an analog signal (e.g., an electrical signal output from the pixel array) into a digital signal. The DSP unit may perform a digital signal processing on the digital signal to generate an image signal. The controller may control the pixel array, the ADC unit, and the DSP unit. Thus, each unit pixel may generate an image signal in a visible light band and an image signal in an infrared light band (e.g., a band having a wavelength longer than about 0.7 μm) without any crosstalk between the image signals, the image sensor 560 may output a high-quality visible light image (e.g., a visible light image having a high resolution) and a high-quality infrared light image (e.g., an infrared light image having a high resolution). Hereinafter, duplicated description for the image sensor 560 will not be repeated.

As described above, the image sensor 560 may operate in an individual mode to generate a color image (e.g., the visible light image) and/or an infrared light image. In an exemplary embodiment, the image sensor 560 may operate in a single mode or in a dual mode. In the single mode of the image sensor 560, the image sensor 560 may generate the color image (e.g., the visible light image) only based on the image signal in a visible light band. In the dual mode of the image sensor 560, the image sensor 560 may generate the color image (e.g., the visible light image) based on both the image signal in the visible light band and the image signal in an infrared light band. Thus, the image sensor 560 may activate the visible light detection pixel of each unit pixel, and may deactivate the infrared light detection pixel of each unit pixel in the single mode of the image sensor 560. In addition, the image sensor 560 may activate the visible light detection pixel and the infrared light detection pixel of each unit pixel in the dual mode of the image sensor 560. In addition, when the image sensor 560 operates in the dual mode, the image sensor 560 may adjust an amount of infrared light absorption of the infrared light detection layer included in the infrared light detection pixel. Thus, the image sensor 560 may adjust sensitivity of the infrared light detection pixel. In an exemplary embodiment, when the image sensor 560 generates the visible light image and the infrared light image, the image sensor 560 may prevent a color mixture of the visible light image due to noises in the infrared light, such noises may be generated from the infrared light cut filter disposed on the visible light detection pixel. The image sensor 560 may eliminate (or reduce) such noises based on information (e.g., infrared light components, or image signals in an infrared light band) output from the infrared light detection pixels. Thus, crosstalk of the infrared light noises may be efficiently prevented (or reduced).

The image sensor 560 may be implemented by various packages such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat-Pack (TQFP), Small Outline Integrated Circuit (SOIC), Shrink Small Outline Package (SSOP), Thin Small Outline Package (TSOP), Thin Quad Flat-Pack (TQFP), System In Package (SIP), Multi Chip Package (MCP), Wafer-level Fabricated Package (WFP), Wafer-Level Processed Stack Package (WSP), or the like. In an exemplary embodiment, the image sensor 560 may be integrated with the processor 510 in one chip. In an exemplary embodiment, the image sensor 560 may be integrated in one chip, and the processor 510 may be integrated in another chip. Although it is illustrated in FIG. 27 that the electronic device 500 is implemented as a smart phone, the electronic device 500 of the present inventive concept is not limited thereto. For example, the electronic device 500 may correspond to a computing system that includes the image sensor 560. In an exemplary embodiment of the present inventive concept, the electronic device 500 may correspond to a cellular phone, a smart phone, a smart pad, a personal digital assistant (PDA), a portable multimedia player (PMP), etc.

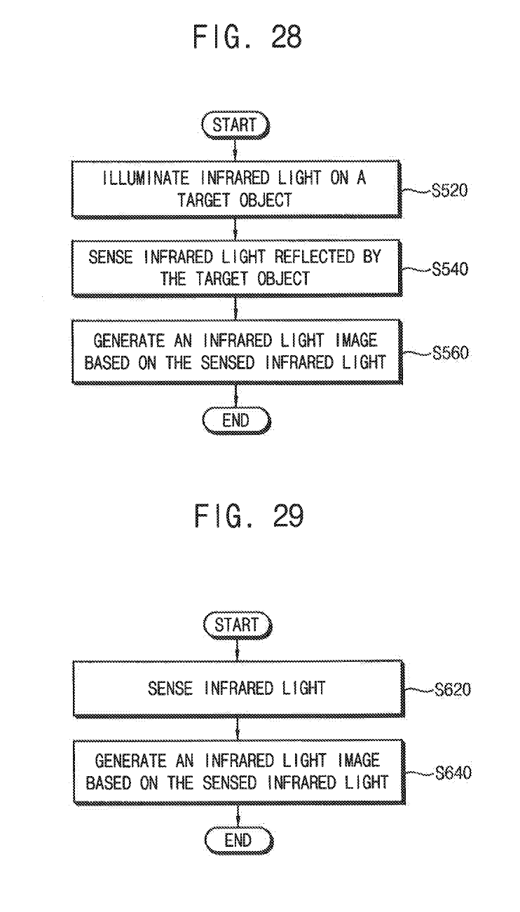

FIG. 28 is a flowchart illustrating an exemplary embodiment of the present inventive concept in which infrared light is sensed by an image sensor included in the electronic device of FIG. 26. FIG. 29 is a flowchart illustrating an exemplary embodiment of the present inventive concept in which infrared light is sensed by an image sensor included in the electronic device of FIG. 26.

Referring to FIGS. 28 and 29, infrared light is sensed by the image sensor 560 included in the electronic device 500. In an exemplary embodiment, as illustrated in FIG. 28, the image sensor 560 included in the electronic device 500 may illuminate infrared light on a target object (S520). To this end, the electronic device 500 or the image sensor 560 included in the electronic device 500 may include an infrared light illumination device that illuminates the infrared light on the target object. In addition, the image sensor 560 included in the electronic device 500 may sense infrared light reflected by the target object (S540), and may generate an infrared light image based on the sensed infrared light (S560). As described above, the image sensor 560 included in the electronic device 500 may sense the infrared light reflected by the target object. For example, the image sensor 560 included in the electronic device 500 may operate according to the above method (e.g., illustrated in FIG. 28) when infrared light is insufficient. In addition, the image sensor 560 included in the electronic device 500 may operate according to the above method (e.g., illustrated in FIG. 28) when the image sensor 560 performs iris recognition, tomography, etc. Further, the image sensor 560 included in the electronic device 500 may operate according to the above method (e.g., illustrated in FIG. 28) when the image sensor 560 is used as a depth sensor that measures a distance (e.g., depth) between the image sensor 560 and the target object. In an exemplary embodiment, as illustrated in FIG. 29, the image sensor 560 included in the electronic device 500 may sense infrared light (S620), and may generate an infrared light image based on the sensed infrared light (S640). For example, the image sensor 560 included in the electronic device 500 may operate according to the above method (e.g., illustrated in FIG. 29) when infrared light for generating the infrared light image is sufficient. Since the above methods are exemplary, a method for sensing infrared light by the image sensor 560 included in the electronic device 500 is not limited thereto.

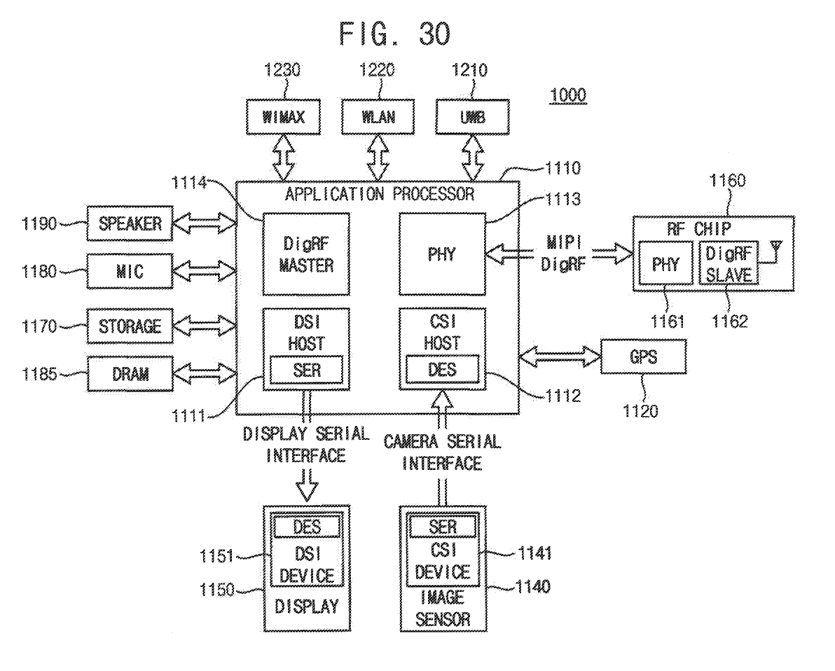

FIG. 30 is a block diagram illustrating an interface used in the electronic device of FIG. 26 according to an exemplary embodiment of the present inventive concept.

Referring to FIG. 30, the electronic device 1000 may be implemented by a data processing device that uses or supports a mobile industry processor interface (MIPI) interface (e.g., a mobile phone, a personal digital assistant (PDA), a portable multimedia player (PMP), a smart phone, etc). The electronic device 1000 may include an application processor (AP) 1010, an image sensor 1140, a display device 1150, and other various input/output devices discussed in detail below. A camera serial interface (CSI) host 1112 of the AP 1110 may perform a serial communication with a CSI device 1141 of the image sensor 1140 using a. CSI. In an exemplary embodiment, the CSI host 1112 may include a light deserializer (DES), and the CSI device 1141 may include a light serializer (SER). A display serial interface (DSI) host 1111 of the AP 1110 may perform a serial communication with a DSI device 1151 of the display device 1150 using a DSI. In an exemplary embodiment, the DSI host 1111 may include a light serializer (SER), and the DSI device 1151 may include a light deserializer (DES). The electronic device 1000 may further include a radio frequency (RF) chip 1160. The RF chip 1160 may perform a communication with the AP 1110. A physical layer (PRY) 1113 of the electronic device 1000 and a PHY 1161 of the RF chip 1160 may perform data communications based on a MIPI DigRF. The AP 1110 may further include a DigRF MASTER 1114 that controls the data communications of the PHY 1161. The electronic device 1000 may include a global positioning system (GPS) 1120, a storage 1170, a microphone (MX) 1180, a DRAM device 1185, a speaker 1190, or the like. The electronic device 1000 may perform communications using an ultra wideband (UWB) 1210, a wireless local area network (WLAN) 1220, a worldwide interoperability for microwave access (WIMAX) 1130, etc. However, a structure and an interface of the electronic device 1000 of the present inventive concept are not limited thereto.

The present inventive concept may be applied to an image sensor and an electronic device including the image sensor. For example, the present inventive concept may be applied to a computer, a laptop, a digital camera, a cellular phone, a smart phone, a video phone, a smart pad, a tablet personal computer (PC), a PDA, a PMP, a navigation system, etc.

The foregoing is illustrative of exemplary embodiments of the present inventive concept and the present inventive concept should not to be construed as being limited by the embodiments described herein. Although a few exemplary embodiments have been described, it will be understood that various modifications in form and detail may be possible without departing from the spirit and scope of the present inventive concept.

1. A unit pixel of an image sensor, comprising:
a visible light detection layer and an infrared light detection layer disposed on the visible light detection layer;
the visible light detection layer includes visible light pixels and color filters configured to detect visible light to output first charges; and
the infrared light detection layer includes at least one infrared light pixel configured to detect infrared light to output second charges.

2. The unit pixel of claim 1, wherein the infrared light detection layer comprises organic material.

3. (canceled)

4. The unit pixel of claim 1, wherein the area of the at least one infrared light pixel is at least 4× the area of at least one of the visible light pixels.

5. The unit pixel of claim 2, wherein each of the at least one infrared light pixel includes electrodes configured to receive a variable bias voltage to adjust rate of infrared light absorption.

6. The unit pixel of claim 1, further including a plurality of storage elements, each corresponding to each infrared light pixel.

7. The unit pixel of claim 1, further including a single storage element for storing the second charges.

8. The unit pixel of claim 1, wherein the infrared light detection layer comprises one of a quantum dot or a III-V compound.

9. The unit pixel of claim 1, further including first signal generation circuit configured to generate first signals corresponding to the first charges and second signal generation circuit configured to generate second signals corresponding to the second charges.

10. The unit pixel of claim 9, further including a mode selection circuit to selectively activate one of the first and second signal generation circuits in single mode operation or activate both the first and second signal generation circuits in dual mode operation.

11. A unit pixel of an image sensor, comprising:
a stacked visible light detection layer, a green light detection layer, and an infrared light detection layer;
the visible light detection layer includes visible light pixels and color filters;
the green light detection layer is made of organic material and includes at least one green light pixel, wherein incident visible light including green light are detected by the visible light detection layer and the green light detection layer and converted to first charges; and
the infrared light detection layer includes at least one infrared light pixel configured to detect and convert infrared light to second charges.

12. The unit pixel of claim 11, wherein the color filters are blue and red filters.

13. The unit pixel of claim 11, wherein the infrared light detection layer is made of organic material.

14. (canceled)

15. The unit pixel of claim 11, wherein the area of the at least one infrared light pixel is at least 4× the area of each of the visible light pixels other than the green pixel.

16. The unit pixel of claim 11, wherein the area of the at least one green light pixel is at least 4× the area of each of the other visible light pixels.

17. (canceled)

18. The unit pixel of claim 11, wherein each of the at least one infrared light pixel includes electrodes configured to receive a variable bias voltage to adjust rate of infrared light absorption.

19. The unit pixel of claim 11, further including a plurality of storage elements, each corresponding to each at least one infrared light pixel.

20. The unit pixel of claim 11, further including a single storage element for storing the second charges.

21. A unit pixel of an image sensor, comprising:
a stacked first visible light detection layer, a second visible light detection layer, a third visible light detection layer, and an infrared light detection layer, each layer is made of organic material and includes a light pixel;
wherein visible light is detected by the light pixels of the first, second, and third visible light detection layers and infrared light is detected by the infrared light pixel.

22. The unit pixel of claim 21, wherein the first visible light detection layer is configured to detect red light, the second visible light detection layer is configured to detect green light, and the third visible light is configured to detect blue light.

23-35. (canceled)
